(19) United States
(12) Patent Application Publication
(10) Pub. No.: US 2026/0201158 A1
(43) Pub. Date: Jul. 16, 2026

(54) RESIN COMPOSITION, PREPREG, FILM WITH RESIN, METAL FOIL WITH RESIN, METAL-CLAD LAMINATE, AND WIRING BOARD

(71) Applicant: PANASONIC INTELLECTUAL PROPERTY MANAGEMENT CO., LTD., Osaka (JP)

(72) Inventors: Hirosuke SAITO, Osaka (JP); Kenta KUBO, Ibaraki (JP)

(73) Assignee: PANASONIC INTELLECTUAL PROPERTY MANAGEMENT CO., LTD., Osaka (JP)

(21) Appl. No.: 19/136,758

(22) PCT Filed: Nov. 10, 2023
(86) PCT No.: PCT/JP2023/040544

§ 371 Date: Jun. 6, 2025

(30) Foreign Application Priority Data
Dec. 15, 2022 (JP) 2022-200257

(51) Int. Cl. C08L 35/00; C08J 5/24; C08L 25/16; C08L 39/04; H05K 1/03

(52) U.S. Cl. CPC C08L 35/00; C08J 5/244; C08L 25/16; C08L 39/04; H05K 1/0366; C08J 2325/16; C08J 2335/00; C08J 2339/04; C08J 2425/06; C08J 2463/00; C08J 2479/08; C08L 2203/20; C08L 2205/03; C08L 2205/035

(57) ABSTRACT

An aspect of the present invention is a resin composition containing a maleimide compound (A) having an aromatic ring in a molecule and a maleimide equivalent of 500 g/mol or less; an imide compound (B) having a weight average molecular weight of 10,000 to 30,000 and a glass transition temperature of 50° C. or less; and a radical polymerizable compound (C).

### TECHNICAL FIELD

The present invention relates to a resin composition, a prepreg, a film with resin, a metal foil with resin, a metal-clad laminate, and a wiring board.

### BACKGROUND ART

In various kinds of electronic equipment, mounting technologies such as higher integration of semiconductor devices to be mounted, higher wiring density, and multi-layering have rapidly progressed along with an increase in the amount of information processed. In addition, as a wiring board used for various electronic equipment, for example, a flip chip ball grid array (BGA) substrate or the like in applications such as servers is required to have a low coefficient of thermal expansion.

Examples of the substrate material for achieving a low coefficient of thermal expansion include the resin compositions described in Patent Literatures 1 and 2.

Patent Literature 1 describes a thermosetting resin composition containing a maleimide compound having at least one N-substituted maleimide group and an inorganic filler, wherein the content of the inorganic filler is from 53 to 65 vol % based on the total amount of the thermosetting resin composition, the thermosetting resin composition further containing a compound having at least two unsaturated aliphatic hydrocarbon groups. Patent Literature 1 discloses that a thermosetting resin composition capable of achieving both low thermal expansion and desmear resistance can be provided.

Patent Literature 2 describes a resin composition containing a compound having a maleimide group, a divalent group having at least two imide bonds, and a saturated or unsaturated divalent hydrocarbon group. Patent Literature 2 discloses that it is possible to provide a resin composition that exhibits excellent high-frequency properties (low relative dielectric constant, low dielectric loss tangent) and also high levels of adhesiveness to conductors, heat resistance, and low moisture absorbing properties.

Hence, substrate materials for forming insulating layers of wiring boards are required to afford cured products having a high glass transition temperature and a low coefficient of thermal expansion.

### CITATION LIST

### Patent Literature

Patent Literature 1: WO 2021/132495 A
Patent Literature 2: WO 2016/114286 A

### SUMMARY OF INVENTION

The present invention has been made in view of such circumstances, and the purpose is to provide a resin composition, which affords a cured product exhibiting a high glass transition temperature and a low coefficient of thermal expansion. Another object of the present invention is to provide a prepreg, a film with resin, a metal foil with resin, a metal-clad laminate, and a wiring board, which are obtained using the resin composition.

An aspect of the present invention is a resin composition containing a maleimide compound (A) having an aromatic ring in a molecule and a maleimide equivalent of 500 g/mol or less; an imide compound (B) having a weight average molecular weight of 10,000 to 30,000 and a glass transition temperature of 50° C. or less; and a radical polymerizable compound (C).

The objects and other objects, features and advantages of the present invention will become apparent from the following detailed description and accompanying drawings.

### BRIEF DESCRIPTION OF DRAWINGS

FIG. 1 is a schematic sectional view illustrating an example of a prepreg according to an embodiment of the present invention.

FIG. 2 is a schematic sectional view illustrating an example of a metal-clad laminate according to an embodiment of the present invention.

FIG. 3 is a schematic sectional view illustrating an example of a wiring board according to an embodiment of the present invention.

FIG. 4 is a schematic sectional view illustrating an example of a metal foil with resin according to an embodiment of the present invention.

FIG. 5 is a schematic sectional view illustrating an example of a film with resin according to an embodiment of the present invention.

### DESCRIPTION OF EMBODIMENTS

Wiring boards used in various kinds of electronic equipment are required to be hardly affected by changes in the external environment, and the like. Substrate materials for forming insulating layers of wiring boards are required to afford cured products exhibiting superior heat resistance such as a high glass transition temperature so that the wiring boards can be used under relatively high temperature conditions. It is also required that insulating layers of wiring boards do not deform even in a relatively high temperature environment. Since this deformation is suppressed when the glass transition temperature of insulating layers is high, the substrate materials for forming insulating layers of wiring boards are required to have a high glass transition temperature.

The wiring board is also required to have small warpage that can occur at the time of chip mounting. In particular, as semiconductor package substrates among wiring boards are increasingly made larger, problems arise that warpage of semiconductor packages on which semiconductor chips are mounted occurs and mounting failures are likely to occur. In order to suppress warpage of semiconductor packages, the insulating layers are required to have a low coefficient of thermal expansion. In particular, the coefficient of thermal expansion in the plane direction is required to be low. Hence, substrate materials for forming insulating layers of wiring boards are required to afford cured products having a low coefficient of thermal expansion.

As a result of extensive studies, the present inventors have found out that the objects, such as providing a resin composition that affords a cured product having a high glass transition temperature and a low coefficient of thermal expansion, are achieved by the present invention below.

Hereinafter, embodiments according to the present invention will be described, but the present invention is not limited thereto.

### [Resin Composition]

A resin composition according to an embodiment of the present invention is a resin composition containing a maleimide compound (A) having an aromatic ring in the molecule and a maleimide equivalent of 500 g/mol or less; an imide compound (B) having a weight average molecular weight of 10,000 to 30,000 and a glass transition temperature of 50° C. or less; and a radical polymerizable compound (C).

In the resin composition, the maleimide compound (A) and the radical polymerizable compound (C) can be suitably cured. The maleimide compound (A) and the radical polymerizable compound (C) may be suitably cured to produce a cured product having a high glass transition temperature. In addition, the imide compound (B) added to the maleimide compound (A) and the radical polymerizable compound (C) is an imide compound having a relatively high weight average molecular weight of 10,000 to 30,000 and a relatively low glass transition temperature of 50° C. or less. Thus, the resulting cured product obtained is a cured product having a low coefficient of thermal expansion (CTE). From these facts, the resin composition may be cured to produce a cured product having a high glass transition temperature and a low coefficient of thermal expansion.

### (Maleimide Compound (A))

The maleimide compound (A) is not particularly limited as long as the maleimide compound has an aromatic ring in the molecule and a maleimide equivalent of 500 g/mol or less. Examples of the maleimide compound (A) include a maleimide compound that is solid at 25° C.

The maleimide equivalent of the maleimide compound (A) is preferably 500 g/mol or less, and more preferably from 200 to 450 g/mol. When the maleimide equivalent is too low, the compatibility with the imide compound (B) decreases, and the maleimide compound (A) tends to be easily separated from the resin composition during preparation of a varnish. When the maleimide equivalent is too high, the cured product obtained tends to have a low glass transition temperature and a high coefficient of thermal expansion. Hence, it is preferable that the maleimide equivalent of the maleimide compound (A) is within the above range from the viewpoint of obtaining a resin composition that can be prepared into a highly uniform varnish and affords a cured product having a low coefficient of thermal expansion. Here, the maleimide equivalent is the mass per 1 mol of maleimide group, and can be calculated, for example, by dividing the molecular weight of the maleimide compound by the number of maleimide groups.

Examples of the aromatic ring include, but are not particularly limited to, a benzene ring, a naphthalene ring, an anthracene ring, a pyrene ring, a pyridine ring, or a furan ring. Among them, a benzene ring is preferable as the aromatic ring.

As the maleimide compound (A), for instance, a maleimide compound having, in the molecule, an arylene structure bonded at the meta position is preferably used from the viewpoints of increasing heat resistance such as a glass transition temperature and increasing compatibility with the imide compound (B), etc. Examples of the arylene structure bonded at the meta position include an arylene structure in which a structure containing a maleimide group is bonded at the meta position (an arylene structure in which a structure containing a maleimide group is substituted at the meta position). The arylene structure bonded at the meta position is an arylene group bonded at the meta position, such as a group represented by the following Formula (2). Examples of the arylene structure bonded at the meta position include m-arylene groups such as a m-phenylene group and a m-naphthylene group, and more specific examples thereof include a group represented by the following Formula (2).

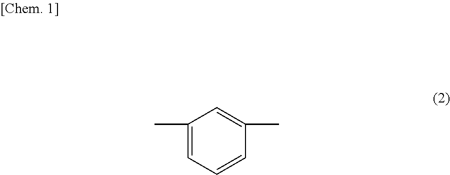

Examples of the maleimide compound (A) include a maleimide compound (A1) represented by the following Formula (3), and more specific examples thereof include a maleimide compound (A2) represented b the following Formula (4).

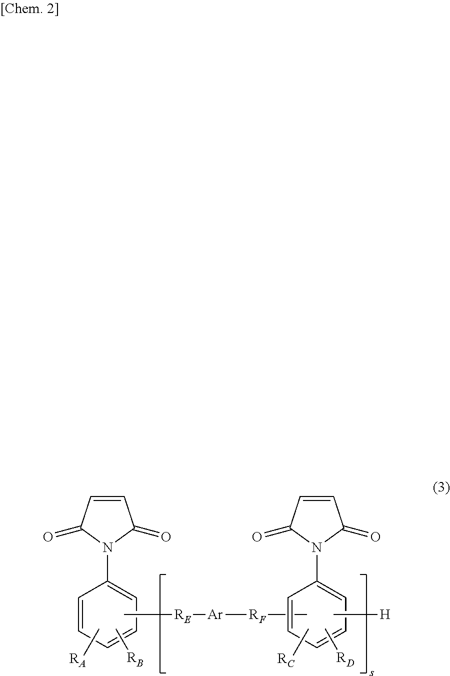

In Formula (3), Ar represents an arylene group bonded at the meta position. R_{A}, R_{B}, R_{C}, and R_{D} are independent of each other. In other words, R_{A}, R_{B}, R_{C}, and R_{D} may be the same group as or different groups from each other. In addition, R_{A}, R_{B}, R_{C}, and R_{D} each represent a hydrogen atom, a C₁₋₅ alkyl group, or a phenyl group, and are each preferably a hydrogen atom. R_{E} and R_{F} are independent of each other. In other words, R_{E} and R_{F} may be the same group as or different groups from each other. In addition, R_{E} and R_{F} each represent an aliphatic hydrocarbon group. s represents 1 to 5.

The arylene group is not particularly limited as long as it is an arylene group bonded at the meta position, examples thereof include m-arylene groups such as a m-phenylene group and a m-naphthylene group, and more specific examples thereof include a group represented by Formula (2).

Examples of the C₁₋₅ alkyl group include a methyl group, an ethyl group, a propyl group, an isopropyl group, a n-butyl group, a sec-butyl group, an isobutyl group, a tert-butyl group, a pentyl group, and a neopentyl group.

The aliphatic hydrocarbon group is a divalent group and may be acyclic or cyclic. Examples of the aliphatic hydrocarbon group include an alkylene group, and more specific examples thereof include a methylene group, a methylmethylene group, and a dimethylmethylene group. Among these, a dimethylmethylene group is preferable.

In the maleimide compound (A1) represented by Formula (3), s, which is the number of repetitions, is preferably 1 to 5. This s is the average value of the number of repetitions (degree of polymerization).

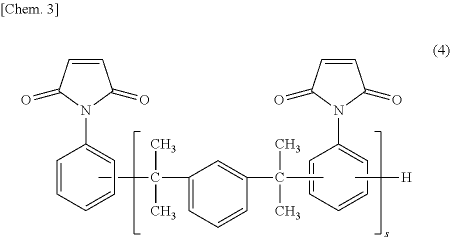

In Formula (4), s represents 1 to 5. This s is the same as s in Formula (3) and is the average value of the number of repetitions (degree of polymerization).

As long as s, which is the average value of the number of repetitions (degree of polymerization), is 1 to 5, the maleimide compound (A1) represented by Formula (3) and the maleimide compound (A2) represented by Formula (4) may include a monofunctional form in which s is 0 or a polyfunctional form such as a heptafunctional form or an octafunctional form in which s is 6 or more.

As the maleimide compound (A), a commercially available product can be used, and for example, the solid component in MIR-5000-60T manufactured by Nippon Kayaku Co., Ltd. may be used.

The maleimide compound (A) is not particularly limited as long as the maleimide compound has an aromatic ring in the molecule and a maleimide equivalent of 500 g/mol or less as described above. In other words, the maleimide compound (A) may be a maleimide compound (another maleimide compound) having an aromatic ring in the molecule and a maleimide equivalent of 500 g/mol or less even if it is other than the maleimide compound exemplified above. The other maleimide compound is a maleimide compound having an aromatic ring in the molecule and a maleimide equivalent of 500 g/mol or less, and examples thereof include a monofunctional maleimide compound having one maleimide group in the molecule, a polyfunctional maleimide compound having two or more maleimide groups in the molecule, and a modified maleimide compound. Examples of the modified maleimide compound include a modified maleimide compound in which a part of the molecule is modified with an amine compound, a modified maleimide compound in which a part of the molecule is modified with a silicone compound, and a modified maleimide compound in which a part of the molecule is modified with an amine compound and a silicone compound. As the maleimide compound (A), the maleimide compounds exemplified above may be used singly or in combination of two or more kinds thereof. As the maleimide compound (A), the maleimide compound (A1) represented by the Formula (3) may be used singly or the maleimide compound (A1) represented by the Formula (3) may be used in combination of two or more kinds thereof.

Examples of the combined use of two or more different kinds of maleimide compounds (A1) represented by Formula (3) include concurrent use of the maleimide compound (A1) represented by Formula (3) other than the maleimide compound (A2) represented by Formula (4) with the maleimide compound (A2) represented by Formula (4).

### (Imide Compound (B))

The imide compound (B) is a compound different from the maleimide compound (A), and is not particularly limited as long as the imide compound has a weight average molecular weight of 10,000 to 30,000 and a glass transition temperature Tg of 50° C. or less, and examples thereof include an imide compound (B-1) having a hydrocarbon group at a molecular end. In addition, examples of the imide compound (B) include, among the imide compounds (B-1), an imide compound (B-1-1) having a structure represented by the following Formula (1) in the molecule as the above imide compound (B).

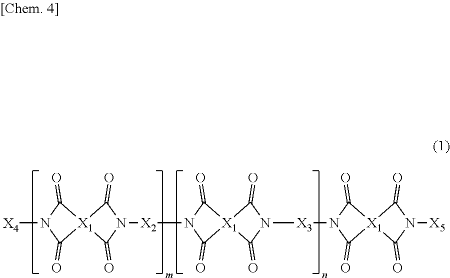

In Formula (1), X₁ represents a tetravalent tetracarboxylic acid residue, X₂ represents a divalent aliphatic diamine residue, X₃ represents a divalent aromatic diamine residue, X₄ and X₅ each independently represent a C₁₋₂₀ hydrocarbon group or an acid anhydride group, at least one of X₄ or X₅ represents a C₁₋₂₀ hydrocarbon group, m represents 1 to 50, n represents 0 to 49, and a sum of m and n represents 1 to 50. As represented by Formula (1), the imide compound (B-1-1) contains the aliphatic diamine residue in the molecule, and may also contain the aromatic diamine residue in the molecule. The imide compound (B-1-1) may be a random copolymer in which the repeating unit containing the aliphatic diamine residue and the repeating unit containing the aromatic diamine residue are present randomly.

The tetracarboxylic acid residue is not particularly limited as long as it is a tetravalent group derived from a tetracarboxylic acid or a tetracarboxylic dianhydride. Examples of the tetracarboxylic acid residue include a residue obtained by eliminating four carboxyl groups from a tetracarboxylic acid, or a residue obtained by eliminating an acid dianhydride structure from a tetracarboxylic dianhydride. Examples of the tetracarboxylic acid residue include C₂₋₄₀ tetravalent tetracarboxylic acid residues.

The aliphatic diamine residue is not particularly limited as long as it is a divalent group derived from an aliphatic diamine compound. Examples of the aliphatic diamine residue include residues obtained by eliminating two amino groups from aliphatic diamine compounds. The aromatic diamine residue is not particularly limited as long as it is a divalent group derived from an aromatic diamine compound. Examples of the aromatic diamine residue include residues obtained by eliminating two amino groups from aromatic diamine compounds.

The hydrocarbon group is not particularly limited as long as it is a C₁₋₂₀ hydrocarbon group. The acid anhydride group is not particularly limited. Examples of the acid anhydride group include an acid anhydride group contained in a tetracarboxylic dianhydride (a raw material of the imide compound (B-1-1)) before the tetracarboxylic acid residue is formed.

In the imide compound (B-1-1), m and n are average values of the number of repeating units (degree of polymerization), and examples of the sum of m and n include the number of repeating units that becomes the below-described acid value of the imide compound (B) or the weight average molecular weight of the imide compound (B). The sum of m and n is, for example, preferably 1 to 50. The ratio [m/(m+n)] of m to the sum of m and n is preferably 0 or more and 0.98 or less [0≤m/(m+n)≤0.98], more preferably 0 or more and 0.5 or less [0≤m/(m+n)≤0.5], and still more preferably 0 or more and 0.4 or less [0≤m/(m+n)≤0.4]. The ratio [m/(m+n)] of m to the sum of m and n represents the proportion of the aliphatic diamine residue in the sum of the aliphatic diamine residue and the aromatic diamine residue.

The acid value of the imide compound (B) is preferably 0 to 50 mgKOH/g, more preferably 0 to 20 mgKOH/g, and still more preferably 0 to 2 mgKOH/g. When the acid value is too high, the compatibility with the maleimide compound (A) is improved, and the cured product obtained tends to have a low glass transition temperature and a high coefficient of thermal expansion. Note that here, the acid value represents the acid value per 1 g of the imide compound (B). The acid value can be measured by potentiometric titration in conformity with DIN EN ISO 2114.

The weight average molecular weight of the imide compound (B) is from 10,000 to 30,000, and preferably from 10,000 to 20,000, as described above. When the weight average molecular weight of the imide compound (B) is too low, the resin viscosity decreases, and the resin flow during press molding tends to be too large. When the weight average molecular weight of the imide compound (B) is too high, the resin viscosity increases, and the resin flow during press molding tends to be too small or the compatibility with the maleimide compound (A) tends to decrease. When the resin flow is too small, for example, there is a risk that the circuit filling properties decrease. When the compatibility with the maleimide compound (A) is too low, the dispersion state in the cured product deteriorates, and there is a risk that the maleimide compound (A) and the imide compound (B) become ununiform. Hence, it is preferable that the weight average molecular weight of the imide compound (B) is within the above range from the viewpoint of moldability and compatibility. Here, the weight average molecular weight may be measured by a general molecular weight measurement method, and specific examples thereof include a value measured by gel permeation chromatography (GPC).

As described above, the glass transition temperature Tg of the imide compound (B) is 50° C. or lower, and preferably 35° C. or lower. When the glass transition temperature Tg of the imide compound (B) is too high, the coefficient of thermal expansion of the resulting cured product of the resin composition tends to increase. In addition, the glass transition temperature Tg of the imide compound (B) is preferably low from the viewpoint of obtaining a cured product having a low coefficient of thermal expansion as the resulting cured product of the resin composition. On the other hand, when the glass transition temperature Tg of the imide compound (B) is too low, the heat resistance of the resulting cured product of the resin composition tends to decrease. Thus, the glass transition temperature Tg is preferably 0° C. or higher, and more preferably 10° C. or higher. Note that examples of the glass transition temperature Tg include a value measured by dynamic viscoelasticity measurement (DMA: Dynamic Mechanical Analysis).

The storage elastic modulus G′ of the imide compound (B) is preferably from 1×10⁵ to 5×10⁸ Pa, and more preferably 1×10⁶ to 1×10⁸ Pa. When the storage elastic modulus G′ is too low, the heat resistance of the resulting cured product of thermal resin composition tends to decrease. When the storage elastic modulus G′ is too high, the coefficient of thermal expansion of the resulting cured product of the resin composition tends to increase. Therefore, when the storage elastic modulus G′ is within the above range, a resin composition that gives a cured product having a higher glass transition temperature and a lower coefficient of thermal expansion is obtained. Examples of the storage elastic modulus G′ include a value measured by dynamic viscoelasticity measurement.

The imide compound (B) [the imide compound (B-1) and the imide compound (B-1-1)] preferably contains an imide group at 2 to 4 mmol/g. When the amount of the imide group is too small, the cured product obtained tends to have a low glass transition temperature and a low coefficient of thermal expansion. When the amount of the imide group is too large, the compatibility with the maleimide compound (A) decreases, and the maleimide compound (A) and imide compound (B) in the cured product tend to be ununiform. Hence, it is preferable that the amount of the imide group is within the above range from the viewpoint of obtaining a resin composition that can be formed into a uniform cured product and affords a cured product having a low coefficient of thermal expansion.

The imide compound (B) may include another imide compound as long as it includes an imide compound having the structure represented by Formula (1) in the molecule.

### (Radical Polymerizable Compound (C))

The radical polymerizable compound (C) is not particularly limited as long as the compound is different from the maleimide compound (A) and has radically polymerizable properties. Examples of the radical polymerizable compound (C) include a compound having an alkenyl group in the molecule. More specific examples thereof include a hydrocarbon-based compound (C-1) having an alkenyl-attached benzene ring in the molecule, an oxazine compound (C-2) having an alkenyl group in the molecule, or an alkenyl compound (C-3) having an alkenyl group in the molecule, which compound is other than the hydrocarbon-based compound (C-1) and the oxazine compound (C-2). These radical polymerizable compounds (C) may be used singly or two or more kinds thereof may be used in combination. In addition, it is preferable that the radical polymerizable compound (C) is free of the alkenyl compound (C-3) from the viewpoint of excellent desmear properties. That is, for example, it is preferable to contain the oxazine compound (C-2). Insulating layers of wiring boards used in various electronic devices are also required to have a property that smear generated by the drilling can be properly removed when drilling is performed using a drill, laser, or the like. Specifically, insulating layers of wiring boards are required to exert excellent desmear properties (e.g., smear can be properly removed with permanganic acid or the like while damage to the insulating layers of wiring boards is suppressed). Hence, substrate materials for forming insulating layers of wiring boards are required to afford cured products exhibiting excellent desmear properties. From the viewpoint of enhancing the desmear properties, it is preferable to contain the oxazine compound (C-2) as the radical polymerizable compound (C). From the viewpoint of further increasing the glass transition temperature, it is preferable to contain, as the radical polymerizable compound (C), at least one selected from the group consisting of the hydrocarbon-based compound (C-1) and the alkenyl compound (C-3), and it is more preferable to contain the hydrocarbon-based compound (C-1). From these, the radical polymerizable compound (C) preferably contains at least one of the hydrocarbon-based compound (C-1) or the oxazine compound (C-2).

The hydrocarbon-based compound (C-1) is not particularly limited as long as the hydrocarbon-based compound has an alkenyl-attached benzene ring in the molecule. Examples of the hydrocarbon-based compound (C-1) include divinylbenzenes such as o-divinylbenzene, m-divinylbenzene, and p-divinylbenzene; a hydrocarbon-based compound represented by the following Formula (5); and a hydrocarbon-based compound represented by the following Formula 7.

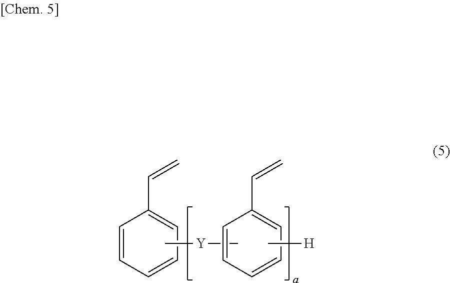

In Formula (5), Y represents a hydrocarbon group having 6 or more carbon atoms and containing at least one selected from an aromatic ring group or an aliphatic ring group. a represents 1 to 10.

The aromatic ring group is not particularly limited, but examples thereof include a phenylene group, a xylylene group, a naphthylene group, a tolylene group, and a biphenylene group. The aliphatic cyclic group is not particularly limited, but examples thereof include a group containing an indane structure and a group containing a cycloolefin structure. Among these, Y is preferably the aromatic ring group, more preferably a xylylene group. The number of carbon atoms in the hydrocarbon group is not particularly limited as long as it is 6 or more, but is preferably 6 to 20. More specific examples of the hydrocarbon-based compound (C-1) [hydrocarbon-based compound represented by Formula (5)] include a hydrocarbon-based compound represented by the following Formula (6). In addition, the hydrocarbon-based compound (C-1) preferably contains a hydrocarbon-based compound represented by the following Formula (6), a hydrocarbon-based compound represented by the following Formula (7), or a divinylbenzene.

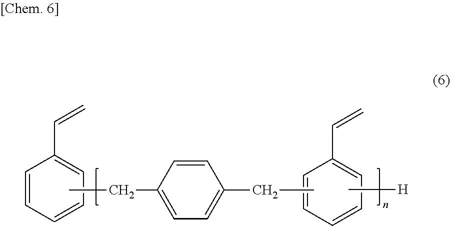

In Formula (6), a represents 1 to 10.

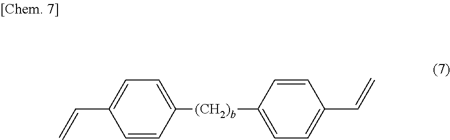

In Formula (7), b represents 0 to 20.

In the compound represented by Formula (7), b is 0 to 20, preferably 1 to 20, more preferably 1 to 12, and still more preferably 1 to 6. Specific examples of the compound represented by Formula (7) include a compound represented by Formula (7) where b is 1 [bis(4-vinylphenyl)methane (BVPM)], a compound represented by Formula (7) where b is 2 [1,2-bis(vinylphenyl)ethane (BVPE)], and a compound represented by Formula (7) where b is 6 [1,6-bis(4-vinylphenyl)hexane (BVPH)].

The oxazine compound (C-2) is not particularly limited as long as the oxazine compound has an alkenyl group in the molecule. Note that the oxazine compound (C-2) has an oxazine group in the molecule. Examples of the oxazine compound (C-2) include a benzoxazine compound (C-2-1) having a benzoxazine group in the molecule. Examples of the benzoxazine group include a benzoxazine group represented by the following Formula (8) and a benzoxazine group represented by the following Formula (9). Examples of the benzoxazine compound (C-2-1) include a benzoxazine compound (C-2-2) having a benzoxazine group represented by the following Formula (8) in the molecule, a benzoxazine compound (C-2-3) having a benzoxazine group represented by the following Formula (9) in the molecule, or a benzoxazine compound (C-2-4) having a benzoxazine group represented by the following Formula (8) and a benzoxazine group represented by the following Formula (9) in the molecule.

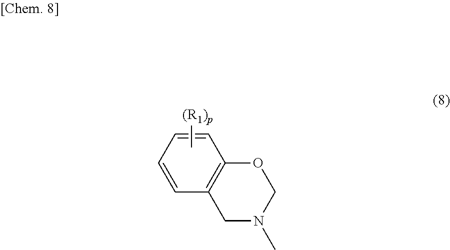

In Formula (8), R₁ represents an allyl group and p represents 1 to 4. p is the average value of the degree of substitution of R₁, and is 1 to 4, preferably 1.

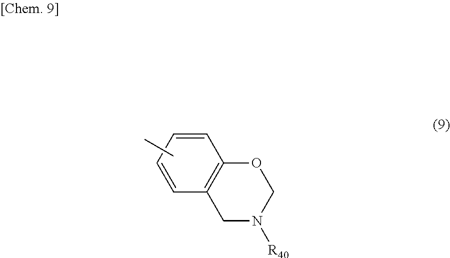

In Formula (9), R₂ represents an allyl group.

Examples of the oxazine compound (C-2), specifically, the benzoxazine compound (C-2-2) include a benzoxazine compound (C-2-5) represented by the following Formula (10).

As the benzoxazine compound (C-2), it is preferable to include the benzoxazine compound (C-2-5).

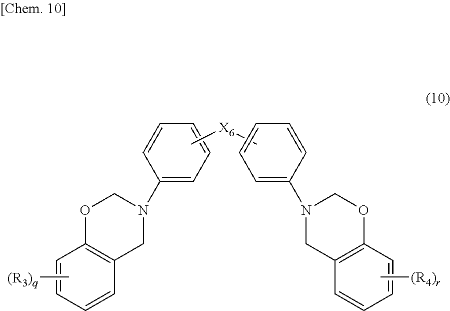

In Formula (10), R₃ and R₄ represent an allyl group, X₆ represents an alkylene group, and q and r each independently represent 1 to 4.

The alkylene group is not particularly limited, and examples thereof include a methylene group, an ethylene group, a propylene group, a butylene group, a pentylene group, a hexylene group, a heptylene group, an octane group, an icosane group, and a hexatriacontane group.

Among these, a methylene group is preferable.

q is the average value of the degree of substitution of R₃, and is 1 to 4, preferably 1. r is the average value of the degree of substitution of R₄, and is 1 to 4, preferably 1.

As the oxazine compound (C-2), a commercially available product can be used, and for example, ALPd manufactured by SHIKOKU CHEMICALS CORPORATION or the like may be used.

As the oxazine compound (C-2), the benzoxazine compounds exemplified above may be used singly or in combination of two or more kinds thereof. For example, as the benzoxazine compound (C-2-1), the benzoxazine compound (C-2-2) having a benzoxazine group represented by Formula (8) in the molecule, the benzoxazine compound (C-2-3) having a benzoxazine group represented by Formula (9) in the molecule, and the benzoxazine compound (C-2-4) having a benzoxazine group represented by Formula (8) and a benzoxazine group represented by Formula (9) in the molecule may each be used singly or may be used in combination of two or more kinds thereof.

The alkenyl compound (C-3) is not particularly limited as long as the alkenyl compound has an alkenyl group in the molecule, which compound is other than the hydrocarbon-based compound (C-1) and the oxazine compound (C-2). Examples of the alkenyl compound (C-3) include a polyphenylene ether compound having a carbon-carbon unsaturated double bond in the molecule, a methacrylate compound, an acrylate compound, a vinyl compound, or an allyl compound.

The polyphenylene ether compound is not particularly limited as long as the polyphenylene ether compound has a carbon-carbon unsaturated double bond in the molecule. Examples of the polyphenylene ether compound include a polyphenylene ether compound having a carbon-carbon unsaturated double bond at the terminal, and more specific examples thereof include a polyphenylene ether compound having a substituent having a carbon-carbon unsaturated double bond at the molecular end, such as a modified polyphenylene ether compound, the end of which is modified with a substituent having a carbon-carbon unsaturated double bond. Examples of the substituent having a carbon-carbon unsaturated double bond include a vinylbenzyl group (ethynylbenzyl group), an acryloyl group, or a methacryloyl group.

The methacrylate compound is a compound having a methacryloyl group in the molecule, and examples thereof include a monofunctional methacrylate compound having one methacryloyl group in the molecule and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include dimethacrylate compounds such as tricyclodecanedimethanol dimethacrylate (DCP).

The acrylate compound is a compound having an acryloyl group in the molecule, and examples thereof include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include: diacrylate compounds such as tricyclodecanedimethanol dimethacrylate.

The vinyl compound is a compound having a vinyl group in the molecule, and examples thereof include a monofunctional vinyl compound (monovinyl compound) having one vinyl group in the molecule and a polyfunctional vinyl compound having two or more vinyl groups in the molecule. Examples of the monofunctional vinyl compound include a vinylbenzene compound with a skeleton having a phosphorus atom in the molecule, such as 9,10-dihydro-9-oxa-10-phospha-phenanthrene-10-oxide (DOPO). More specific examples thereof include a compound represented by the following Formula (11).

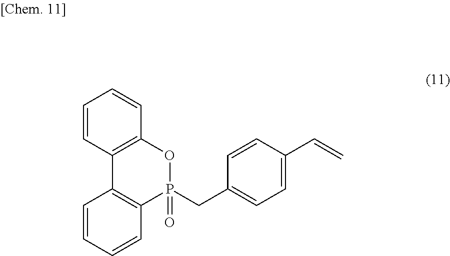 [SMILES: C=Cc1ccc(CP2(=O)Oc3ccccc3-c3ccccc32)cc1]

The allyl compound is a compound having an allyl group in the molecule, and examples thereof include a triallyl isocyanurate compound such as triallyl isocyanurate (TAIC), a diallyl bisphenol compound, and diallyl phthalate (DAP).

As the radical polymerizable compound (C), the radical polymerizable compounds exemplified above may be used singly or in combination of two or more kinds thereof.

### (Styrenic Polymer (D))

The resin composition may further contain a styrenic polymer (D), and preferably contains the styrenic polymer (D). In electronic devices, particularly in small portable devices such as portable communication terminals and notebook computers, diversification, improvement in performance, thinning, and miniaturization have rapidly proceeded. Along with this, in wiring boards used in these products as well, there is a further demand for refinement of conductor wiring, multilayering of conductor wiring layers, thinning, and improvement in performance such as mechanical properties. For this reason, in the wiring boards, it is required that the wirings do not peel off from the insulating layers although provided wirings are refined wirings. In order to meet this requirement, in the wiring boards, it is required that the adhesion between wirings and insulating layers is high. Hence, it is required that the adhesion between metal foils and insulating layers is high in metal-clad laminates, and substrate materials for forming insulating layers of wiring boards are required to afford cured products exhibiting excellent adhesion to metal foils. As described above, wiring boards are required to be multi-layered and are also required to exhibit high interlayer adhesion so that delamination between an insulating layer and another insulating layer does not occur when insulating layers are constituted of multiple layers. For this reason, substrate materials for forming insulating layers of the wiring boards are required to afford cured products, which are excellent in adhesion between adjacent cured products, namely, interlayer adhesion. By containing the styrenic polymer (D), a resin composition is obtained that gives a cured product excellent in adhesion to a metal foil and interlayer adhesion as described above. That is, by containing the styrenic polymer (D), a resin composition can be obtained that gives a cured product having not only a high glass transition temperature and a low coefficient of thermal expansion but also excellent adhesion to a metal foil and interlayer adhesion. Examples of the styrenic polymer (D) include, but are not particularly limited to, a styrenic polymer that is solid at 25° C. More specific examples include styrenic polymers that are solid at 25° C. and can be used as resins contained in resin compositions used for forming insulating layers of metal-clad laminates, wiring boards and the like. The resin compositions used for forming insulating layers of metal-clad laminates, wiring boards and the like may be resin compositions used for forming resin layers of films with resin, metal foils with resin and the like, or may be a resin composition contained in prepregs.

The styrenic polymer (D) is, for example, a polymer obtained by polymerizing a monomer including a styrenic monomer, and may be a styrenic copolymer. Examples of the styrenic copolymer include: copolymers obtained by copolymerizing one or more styrenic monomers and one or more of other monomers copolymerizable with the styrenic monomers. The styrenic copolymer may be a random copolymer or a block copolymer as long as a structure derived from the styrenic monomer is included in the molecule. Examples of the block copolymer include a binary copolymer of the structure (repeating unit) derived from the styrenic monomer and the other copolymerizable monomer (repeating unit), a ternary copolymer of the structure (repeating unit) derived from the styrenic monomer, the other copolymerizable monomer (repeating unit), and the structure (repeating unit) derived from the styrenic monomer, and a ternary copolymer of the structure (repeating unit) derived from the styrenic monomer, a randomly copolymerized block (repeating unit) containing the other copolymerizable monomer and the styrenic monomer, and a structure (repeating unit) derived from the styrenic monomer. The styrenic polymer (D) may be a hydrogenated styrenic copolymer obtained by hydrogenating the styrenic copolymer. The styrenic polymer (D) is preferably at least partly hydrogenated. By containing a styrenic polymer that is at least partly hydrogenated, a resin composition can be obtained which gives a cured product exhibiting superior adhesion to metal foils and superior dimensional stability. In addition, the styrene-based polymer (D) may be the styrenic copolymer, the styrenic polymer, at least part of which is hydrogenated, or the hydrogenated styrenic copolymer, a part of which is modified with maleic anhydride.

The styrenic monomer is not particularly limited, but examples thereof include styrene, a styrene derivative, one in which some hydrogen atoms of the benzene ring in styrene are substituted with an alkyl group, one in which some hydrogen atoms of the vinyl group in styrene are substituted with an alkyl group, vinyltoluene, α-methylstyrene, butylstyrene, dimethylstyrene, and isopropenyltoluene. As the styrenic monomer, these may be used singly or in combination of two or more kinds thereof. The other copolymerizable monomer is not particularly limited, and examples thereof include olefins such as α-pinene, β-pinene, and dipentene, unconjugated dienes such as 1,4-hexadiene and 3-methyl-1,4-hexadiene, and conjugated dienes such as 1,3-butadiene and 2-methyl-1,3-butadiene (isoprene). As the other copolymerizable monomer, these may be used singly or in combination of two or more kinds thereof.

As the styrenic polymer (D), conventionally known ones can be widely used, the styrenic polymer (D) is not particularly limited, but examples thereof include a polymer having a structural unit represented by the following Formula (12) (a structure derived from the styrenic monomer) in the molecule.

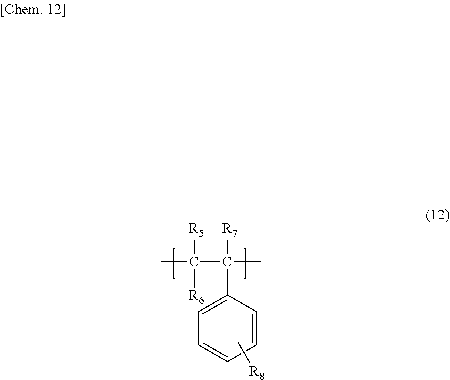

In Formula (12), R₅ to R₇ each independently represent a hydrogen atom or an alkyl group, and R₈ represents any group selected from the group consisting of a hydrogen atom, an alkyl group, an alkenyl group, and an isopropenyl group. The alkyl group is not particularly limited and is, for example, preferably a C₁₋₁₈ alkyl group, and more preferably a C₁₋₁₀ alkyl group. Specific examples thereof include a methyl group, an ethyl group, a propyl group, a hexyl group, and a decyl group. The alkenyl group is preferably a C₁₋₁₀ alkenyl group.

The styrenic polymer (D) preferably contains at least one structural unit represented by Formula (12), and may contain two or more different structural units in combination. In addition, the styrenic polymer (D) may contain a structure in which the structural unit represented by Formula (12) is repeated.

In addition to the structural unit represented by Formula (12), the styrenic polymer (D) may have, as a structural unit derived from another monomer that is copolymerizable with the styrenic monomer, at least one among structural units represented by the following Formula (13), the following Formula (14), and the following Formula (15) and structures in which structural units represented by the following Formula (13), the following Formula (14), and the following Formula (15) are each repeated.

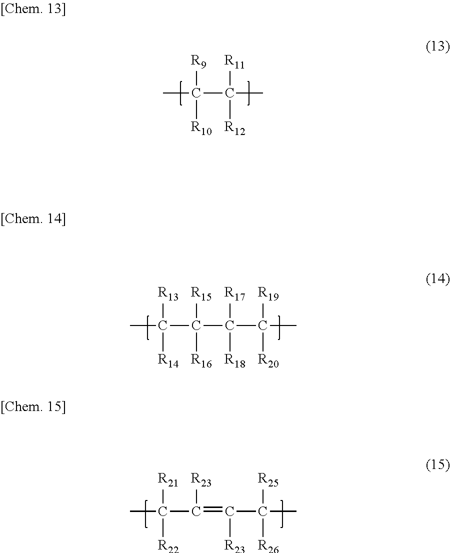

In Formula (13), Formula (14), and Formula (15), R₉ to R₂₆ each independently represent any group selected from the group consisting of a hydrogen atom, an alkyl group, an alkenyl group, and an isopropenyl group. The alkyl group is not particularly limited and is, for example, preferably a C₁₋₁₈ alkyl group, and more preferably a C₁₋₁₀ alkyl group. Specific examples thereof include a methyl group, an ethyl group, a propyl group, a hexyl group, and a decyl group. The alkenyl group is preferably a C₁₋₁₀ alkenyl group.

The styrenic polymer (D) preferably contains at least one among the structural units represented by Formula (13), Formula (14), and Formula (15), and may contain two or more different structural units among these in combination. The styrenic polymer may have at least one among the structures in which the structural units represented by Formula (13), Formula (14), and Formula (15) are each repeated.

More specific examples of the structural unit represented by Formula (12) include structural units represented by the following Formulas (16) to (18). The structural unit represented by Formula (12) may be structures in which structural units represented by the following Formulas (16) to (18) are each repeated, and the like. The structural unit represented by Formula (12) may be one structural unit among these or a combination of two or more different structural units.

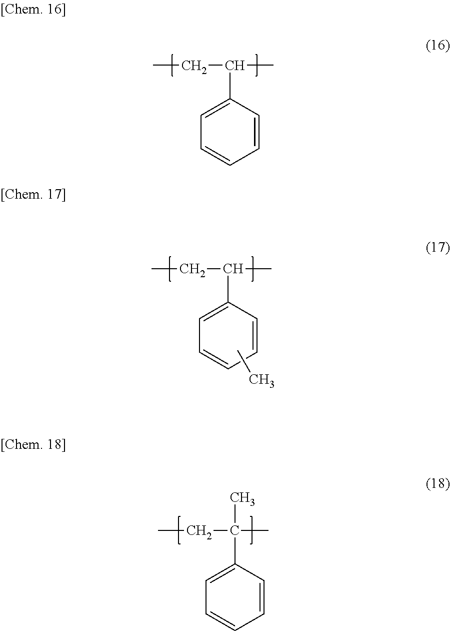

More specific examples of the structural unit represented by Formula (13) include structural units represented by the following Formulas (19) to (25). The structural unit represented by Formula (13) may be structures in which structural units represented by the following Formulas (19) to (25) are each repeated, and the like. The structural unit represented by Formula (13) may be one structural unit among these or a combination of two or more different structural units.

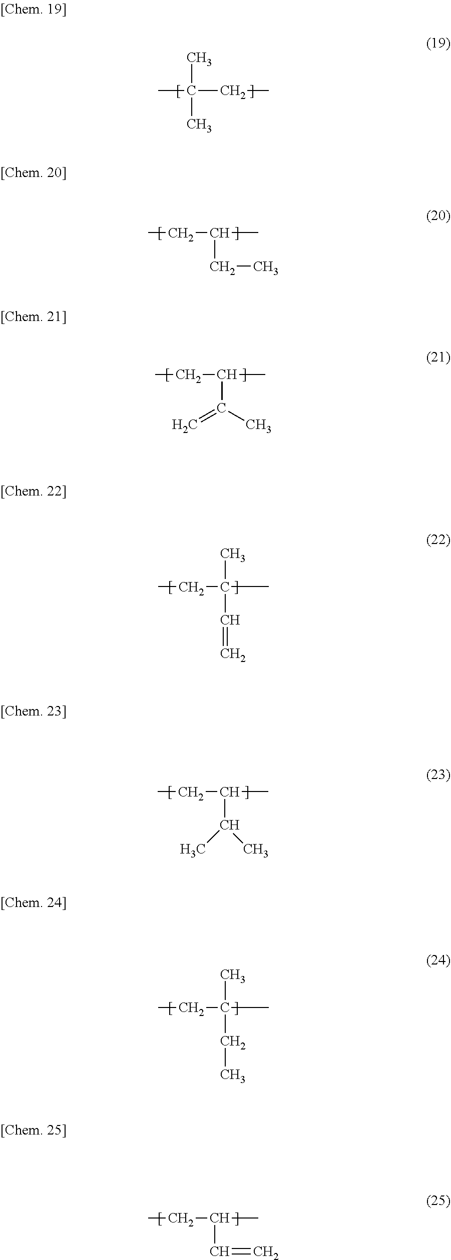

More specific examples of the structural unit represented by Formula (14) include structural units represented by the following Formulas (26) and (27). The structural unit represented by Formula (14) may be structures in which structural units represented by the following Formulas (28) and (29) are each repeated, and the like. The structural unit represented by Formula (14) may be one structural unit among these or a combination of two or more different structural units.

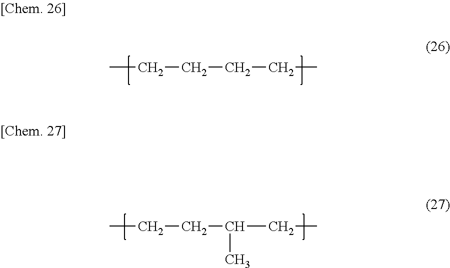

More specific examples of the structural unit represented by Formula (15) include structural units represented by the following Formulas (28) and (29). The structural unit represented by Formula (15) may be structures in which structural units represented by the following Formulas (28) and (29) are each repeated, and the like. The structural unit represented by Formula (15) may be one structural unit among these or a combination of two or more different structural units.

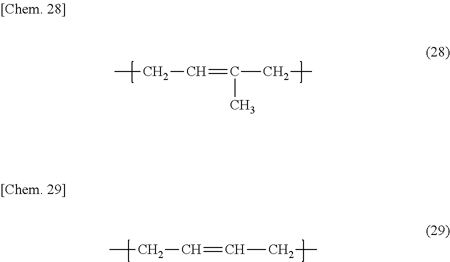

Preferred examples of the styrenic copolymer (D) include polymers or copolymers obtained by polymerizing or copolymerizing one or more styrenic monomers such as styrene, vinyltoluene, α-methylstyrene, isopropenyltoluene, divinylbenzene, or allylstyrene.

More specific examples of the styrenic polymer (D) include a methylstyrene (ethylene/butylene) methylstyrene block copolymer, a methylstyrene (ethylene-ethylene/propylene) methylstyrene block copolymer, a styrene isoprene block copolymer, a styrene isoprene styrene block copolymer, a styrene (ethylene/butylene) styrene block copolymer, a styrene (ethylene-ethylene/propylene) styrene block copolymer, a styrene butadiene block copolymer such as a styrene butadiene styrene block copolymer, a styrene isobutylene styrene block copolymer, a styrene (butadiene/butylene) styrene block copolymer, a methylstyrene (styrene/butadiene random copolymer block) methylstyrene copolymer, a styrene (styrene/butadiene random copolymer block) styrene copolymer, and hydrogenated products in which these are at least partly hydrogenated.

As the styrenic polymer (D), a commercially available product can be used, and for example, Tuftec P1500, Tuftec H1041, Tuftec H1517, and Tuftec M1913 manufactured by Asahi Kasei Corporation and Asaprene T437 manufactured by Asahi Kasei Corporation may be used.

As the styrenic polymer (D), the styrenic polymers exemplified above may be used singly or in combination of two or more kinds thereof.

The weight average molecular weight of the styrenic polymer (D) is preferably 1,000 to 300,000, and more preferably 10,000 to 200,000. When the molecular weight is too low, the glass transition temperature or heat resistance of the cured product of the resin composition tends to decrease. When the molecular weight is too high, the viscosity of the resin composition when prepared in the form of a varnish and the viscosity of the resin composition during heat molding tend to be too high. The weight average molecular weight is only required to be one measured by a general molecular weight measurement method, and specific examples thereof include a value measured by gel permeation chromatography (GPC).

### (Inorganic Filler)

The resin composition may contain an inorganic filler, if necessary, as long as the effects of the present invention are not impaired. It is preferable to contain the inorganic filler from the viewpoint of enhancing the heat resistance and the like of the cured product of the resin composition. The inorganic filler is not particularly limited as long as it is an inorganic filler that can be used as an inorganic filler contained in a resin composition. Examples of the inorganic filler include a silica filler, an alumina filler, a metal oxide filler (e.g., a titanium oxide filler, a magnesium oxide filler, a mica filler), a metal hydroxide filler (e.g., a magnesium hydroxide filler, an aluminum hydroxide filler), a talc filler, an aluminum borate filler, a barium sulfate filler, an aluminum nitride filler, a boron nitride filler, a barium titanate filler, a strontium titanate filler, a calcium titanate filler, an aluminum titanate filler, a magnesium carbonate filler (e.g., an anhydrous magnesium carbonate filler), a calcium carbonate filler, a molybdate compound filler (e.g., a zinc molybdate filler, a calcium molybdate filler), or a talc filler carrying the molybdate compound. Among them, a silica filler, a metal hydroxide filler (e.g., a magnesium hydroxide filler, an aluminum hydroxide filler), an aluminum oxide filler, a boron nitride filler, a strontium titanate filler, a calcium titanate filler, a zinc molybdate filler, or the like is preferable. A silica filler is more preferred. The silica filler is not particularly limited, examples thereof include crushed silica, spherical silica, and silica particles, and spherical silica is preferable. As the inorganic filler, the exemplified inorganic fillers may each be used singly, or two or more kinds thereof may be used in combination. When two or more kinds of the inorganic fillers are used in combination, a silica filler and one or more kinds of inorganic fillers other than the silica filler may be used in combination, and it is preferable to use a silica filler and a zinc molybdate filler in combination.

The inorganic filler may be an inorganic filler subjected to a surface treatment or an inorganic filler not subjected to a surface treatment. Examples of the surface treatment include treatment with a silane coupling agent.

The silane coupling agent is not particularly limited, and examples thereof include a silane coupling agent having at least one functional group selected from the group consisting of a vinyl group, a styryl group, a methacryloyl group, an acryloyl group, a phenylamino group, an isocyanurate group, a ureido group, a mercapto group, an isocyanate group, an epoxy group, and an acid anhydride group. In other words, examples of this silane coupling agent include compounds having at least one of a vinyl group, a styryl group, a methacryloyl group, an acryloyl group, a phenylamino group, an isocyanurate group, a ureido group, a mercapto group, an isocyanate group, an epoxy group, and an acid anhydride group as a reactive functional group, and further a hydrolyzable group such as a methoxy group or an ethoxy group.

Examples of the silane coupling agent include vinyltriethoxysilane and vinyltrimethoxysilane as those having a vinyl group. Examples of the silane coupling agent include p-styryltrimethoxysilane and p-styryltriethoxysilane as those having a styryl group. Examples of the silane coupling agent include 3-methacryloxypropyltrimethoxysilane, 3-methacryloxypropylmethyldimethoxysilane, 3-methacryloxypropyltriethoxysilane, 3-methacryloxypropylmethyldiethoxysilane, and 3-methacryloxypropylethyldiethoxysilane as those having a methacryloyl group. Examples of the silane coupling agent include 3-acryloxypropyltrimethoxysilane and 3-acryloxypropyltriethoxysilane as those having an acryloyl group. Examples of the silane coupling agent include N-phenyl-3-aminopropyltrimethoxysilane and N-phenyl-3-aminopropyltriethoxysilane as those having a phenylamino group.

The average particle size of the inorganic filler is not particularly limited, and is preferably 0.05 to 10 μm and more preferably 0.1 to 8 μm. Here, the average particle size refers to the volume average particle size. The volume average particle size can be measured by, for example, a laser diffraction method and the like.

### (Content)

The content of the maleimide compound (A) is preferably 30 to 80 parts by mass and more preferably 35 to 70 parts by mass based on total 100 parts by mass of the maleimide compound (A), the imide compound (B), and the radical reactive compound (C). When the content of the maleimide compound (A) is within the above range, a resin composition that can give a cured product having a high glass transition temperature and a low coefficient of thermal expansion is more suitably obtained.

The content of the imide compound (B) is preferably 5 to 40 parts by mass, more preferably 10 to 35 parts by mass based on total 100 parts by mass of the maleimide compound (A), the imide compound (B), and the radical polymerizable compound (C). When the content of the imide compound (B) is within the above range, a resin composition that can give a cured product having a high glass transition temperature and a low coefficient of thermal expansion is more suitably obtained.

The content of the radical polymerizable compound (C) is preferably 5 to 50 parts by mass and more preferably 10 to 45 parts by mass based on total 100 parts by mass of the maleimide compound (A), the imide compound (B), and the radical reactive compound (C). When the content of the radical polymerizable compound (C) is within the above range, a resin composition that can give a cured product having a high glass transition temperature and a low coefficient of thermal expansion is more suitably obtained.

When the contents of the maleimide compound (A), the imide compound (B), and the radical polymerizable compound (C) are each within the above ranges, as described above, a resin composition that can give a cured product having a high glass transition temperature and a low coefficient of thermal expansion is more suitably obtained. This is considered to be due to the fact that each of the effect exhibited by containing the maleimide compound (A), the effect exhibited by containing the imide compound (B), and the effect exhibited by containing the radical polymerizable compound (C) can be fully exerted when the contents of the maleimide compound (A), the imide compound (B), and the radical polymerizable compound (C) are each within the above ranges.

The resin composition may contain the styrenic polymer (D) as described above. When the resin composition contains the styrenic polymer (D), the contents of the maleimide compound (A), the imide compound (B), the radically reactive compound (C), and the styrenic polymer (D) are preferably within the following ranges.

The content of the maleimide compound (A) is preferably 30 to 70 parts by mass, and more preferably 30 to 60 parts by mass, based on total 100 parts by mass of the maleimide compound (A), the imide compound (B), the radical reactive compound (C), and the styrenic polymer (D).

The content of the imide compound (B) is preferably 5 to 40 parts by mass, and more preferably 5 to 30 parts by mass, based on total 100 parts by mass of the maleimide compound (A), the imide compound (B), the radical reactive compound (C), and the styrenic polymer (D).

The content of the radical polymerizable compound (C) is preferably 5 to 50 parts by mass, and more preferably 10 to 45 parts by mass, based on total 100 parts by mass of the maleimide compound (A), the imide compound (B), the radical reactive compound (C), and the styrenic polymer (D).

The content of the styrenic polymer (D) is preferably 5 to 40 parts by mass, and more preferably 10 to 30 parts by mass, based on total 100 parts by mass of the maleimide compound (A), the imide compound (B), the radical reactive compound (C), and the styrenic polymer (D).

The resin composition may contain the inorganic filler as described above. When the resin composition contains the inorganic filler, the content of the inorganic filler is preferably 50 to 300 parts by mass based on total 100 parts by mass of the maleimide compound (A), the imide compound (B), and the radical polymerizable compound (C).

### (Other Components)

The resin composition may contain components (other components) other than the maleimide compound (A), the imide compound (B), and the radical polymerizable compound (C) as long as the effects of the present invention are not impaired. As described above, the resin composition may contain the styrenic polymer (D) and the inorganic filler as the other components. Examples of the other components other than the styrenic polymer and the inorganic filler include an organic component other than the maleimide compound (A), the imide compound (B), the radical polymerizable compound (C), and the styrenic polymer (D) and additives such as a flame retardant, a reaction initiator, a curing accelerator, a catalyst, a polymerization retarder, a polymerization inhibitor, a dispersant, a leveling agent, a coupling agent, an antifoaming agent, an antioxidant, a heat stabilizer, an antistatic agent, an ultraviolet absorber, a dye or a pigment, and a lubricant.

As described above, the resin composition according to the present embodiment may contain an organic component other than the maleimide compound (A), the imide compound (B), the radical polymerizable compound (C), and the styrenic polymer (D). The organic component may be, for example, a compound that reacts with at least one of the maleimide compound (A), the imide compound (B), and the radical polymerizable compound (C), or may be a compound that does not react therewith. Specific examples of the organic component include an oxazine compound (other oxazine compound) other than the oxazine compound (C-1), an epoxy compound, a cyanic acid ester compound, or an active ester compound.

The other oxazine compound is not particularly limited as long as it has an oxazine group in the molecule and is an oxazine compound other than the oxazine compound (C-1). Examples of the other oxazine compound include a benzoxazine compound (phenolphthalein-type benzoxazine compound) having a phenolphthalein structure in the molecule, a bisphenol F-type benzoxazine compound, and a diaminodiphenylmethane (DDM)-type benzoxazine compound. More specific examples of the other oxazine compound include 3,3′-(methylene-1,4-diphenylene)bis(3,4-dihydro-2H-1,3-benzoxazine) (P-d type benzoxazine compound) and 2,2-bis(3,4-dihydro-2H-3-phenyl-1,3-benzoxazine)methane (F-a type benzoxazine compound).

The epoxy compound is a compound having an epoxy group in the molecule, and specific examples thereof include a bisphenol type epoxy compound such as a bisphenol A type epoxy compound, a phenol novolac type epoxy compound, a cresol novolac type epoxy compound, a dicyclopentadiene type epoxy compound, a bisphenol A novolac type epoxy compound, a biphenylaralkyl type epoxy compound, a polybutadiene compound having an epoxy group in the molecule, and a naphthalene ring-containing epoxy compound. The epoxy compound also includes an epoxy resin, which is a polymer of each of the epoxy compounds.

The cyanate ester compound is a compound having a cyanato group in the molecule, and examples thereof include 2,2-bis(4-cyanatophenyl)propane, bis(3,5-dimethyl-4-cyanatophenyl)methane, and 2,2-bis(4-cyanatophenyl)ethane.

The active ester compound is a compound having an ester group exhibiting high reaction activity in the molecule, and examples thereof include a benzenecarboxylic acid active ester, a benzenedicarboxylic acid active ester, a benzenetricarboxylic acid active ester, a benzenetetracarboxylic acid active ester, a naphthalenecarboxylic acid active ester, a naphthalenedicarboxylic acid active ester, a naphthalenetricarboxylic acid active ester, a naphthalenetetracarboxylic acid active ester, a fluorenecarboxylic acid active ester, a fluorenedicarboxylic acid active ester, a fluorenetricarboxylic acid active ester, and a fluorenetetracarboxylic acid active ester.

As described above, the resin composition according to the present embodiment may contain a flame retardant. The flame retardancy of a cured product of the resin composition can be enhanced by containing a flame retardant. The flame retardant is not particularly limited. Specifically, in the field in which halogen-based flame retardants such as bromine-based flame retardants are used, for example, ethylenedipentabromobenzene, ethylenebistetrabromoimide, decabromodiphenyloxide, and tetradecabromodiphenoxybenzene that have a melting point of 300° C. or more, and a bromostyrene-based compound that reacts with the polymerizable compound are preferable. It is considered that the elimination of halogen at a high temperature and the decrease in heat resistance can be suppressed by the use of a halogen-based flame retardant. There is a case where a flame retardant containing phosphorus (phosphorus-based flame retardant) is used in fields required to be halogen-free. The phosphorus-based flame retardant is not particularly limited, and examples thereof include a phosphate ester-based flame retardant, a phosphazene-based flame retardant, a bis(diphenylphosphine oxide)-based flame retardant, a 9,10-dihydro-9-oxa-10-phosphaphenanthrene-10-oxide (DOPO)-based flame retardant, and a phosphinate salt-based flame retardant. Specific examples of the phosphate ester-based flame retardant include a condensed phosphate ester such as dixylenyl phosphate. Specific examples of the phosphazene-based flame retardant include phenoxyphosphazene. Specific examples of the bis(diphenylphosphine oxide)-based flame retardant include xylylenebis(diphenylphosphine oxide). Specific examples of the DOPO-based flame retardant include hydrocarbons having two DOPO groups in the molecule (DOPO derivative compounds) and DOPO having a reactive functional group. Specific examples of the phosphinate-based flame retardant include metal phosphinates such as an aluminum dialkyl phosphinate. As the flame retardant, the respective flame retardants exemplified may be used singly or in combination of two or more kinds thereof.

As described above, the resin composition according to the present embodiment may contain a reaction initiator. The reaction initiator is not particularly limited as long as it can promote the curing reaction of the resin composition, and examples thereof include a peroxide and an organic azo compound. Examples of the peroxide include α,α′-di(t-butylperoxy)diisopropylbenzene (PBP), 2,5-dimethyl-2,5-di(t-butylperoxy)-3-hexyne, and benzoyl peroxide. Examples of the organic azo compound include azobisisobutyronitrile. A metal carboxylate can be concurrently used if necessary. By doing so, the curing reaction can be further promoted. Among these, α,α′-di(t-butylperoxy)diisopropylbenzene is preferably used. α,α′-Di(t-butylperoxy)diisopropylbenzene has a relatively high reaction initiation temperature and thus can suppress the promotion of the curing reaction at the time point at which curing is not required, for example, at the time of prepreg drying, and can suppress a decrease in storage stability of the resin composition. α,α′-Di(t-butylperoxy)diisopropylbenzene exhibits low volatility, and thus does not volatilize at the time of prepreg drying and storage, and exhibits favorable stability. The reaction initiators may be used singly or in combination of two or more kinds thereof.

As described above, the resin composition according to the present embodiment may contain a curing accelerator. The curing accelerator is not particularly limited as long as it can promote the curing reaction of the resin composition. Specific examples of the curing accelerator include imidazoles and derivatives thereof, organophosphorus compounds, amines such as secondary amines and tertiary amines, quaternary ammonium salts, organoboron compounds, and metal soaps. Examples of the imidazoles include 2-ethyl-4-methylimidazole (2E4MZ), 2-methylimidazole, 2-phenyl-4-methylimidazole, 2-phenylimidazole, and 1-benzyl-2-methylimidazole. Examples of the organophosphorus compounds include triphenylphosphine, diphenylphosphine, phenylphosphine, tributylphosphine, and trimethylphosphine. Examples of the amines include dimethylbenzylamine, triethylenediamine, triethanolamine, and 1,8-diaza-bicyclo(5,4,0)undecene-7 (DBU). Examples of the quaternary ammonium salts include tetrabutylammonium bromide. Examples of the organoboron compounds include tetraphenylboron salts such as 2-ethyl-4-methylimidazole-tetraphenylborate and tetra-substituted phosphonium/tetra-substituted borate such as tetraphenylphosphonium/ethyltriphenylborate. The metal soap refers to a fatty acid metal salt, and may be a linear fatty acid metal salt or a cyclic fatty acid metal salt. Specific examples of the metal soaps include C₆₋₁₀ linear aliphatic metal salts and cyclic aliphatic metal salts. More specific examples thereof include aliphatic metal salts formed from linear fatty acids such as stearic acid, lauric acid, ricinoleic acid, and octylic acid and cyclic fatty acids such as naphthenic acid and metals such as lithium, magnesium, calcium, barium, copper, and zinc. Examples thereof include zinc octylate. The curing accelerators may be used singly or in combination of two or more kinds thereof.

As described above, the resin composition according to the present embodiment may contain a silane coupling agent. The silane coupling agent may be contained in the resin composition or may be contained as a silane coupling agent covered on the inorganic filler contained in the resin composition for surface treatment in advance. Among them, it is preferable that the silane coupling agent is contained as a silane coupling agent covered on the inorganic filler for surface treatment in advance, and it is more preferable that the silane coupling agent is contained as a silane coupling agent covered on the inorganic filler for surface treatment in advance and further is also contained in the resin composition. In the case of a prepreg, the silane coupling agent may be contained in the prepreg as a silane coupling agent covered on the fibrous base material for surface treatment in advance. Examples of the silane coupling agent include those similar to the silane coupling agents used in the surface treatment of the inorganic filler described above.

The resin composition according to the present embodiment is a resin composition that can give a cured product having a high glass transition temperature and a low coefficient of thermal expansion.

### (Use)

The resin composition is used when a prepreg is manufactured, as described later. The resin composition is used when a resin layer included in a metal foil with resin and a film with resin is formed and when an insulating layer included in a metal-clad laminate and a wiring board is formed.

### (Production Method)

The method for producing the resin composition is not particularly limited, and examples thereof include a method in which the maleimide compound (A), the imide compound (B), the radical polymerizable compound (C), and if necessary, components other than the maleimide compound (A), the imide compound (B), and the radical polymerizable compound (C), are mixed together so as to have predetermined contents. Examples thereof include the method to be described later in the case of obtaining a varnish-like composition containing an organic solvent.

By using the resin composition according to the present embodiment, a prepreg, a metal-clad laminate, a wiring board, a metal foil with resin, and a film with resin can be obtained as described below.

### [Prepreg]

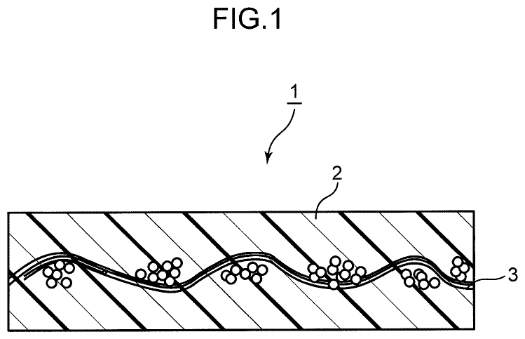

FIG. 1 is a schematic sectional view illustrating an example of a prepreg 1 according to an embodiment of the present invention.

As illustrated in FIG. 1, the prepreg 1 according to the present embodiment includes the resin composition or a semi-cured product 2 of the resin composition and a fibrous base material 3. This prepreg 1 includes the resin composition or the semi-cured product 2 of the resin composition and the fibrous base material 3 present in the resin composition or the semi-cured product 2 of the resin composition.

In the present embodiment, the semi-cured product is in a state in which the resin composition has been cured to an extent that the resin composition can be further cured. In other words, the semi-cured product is the resin composition in a semi-cured state (B-staged). For example, when a resin composition is heated, the viscosity of the resin composition first gradually decreases, then curing starts, and the viscosity gradually increases. In such a case, the semi-cured state includes a state where the viscosity has started to increase but curing is not completed, and the like.

The prepreg to be obtained using the resin composition according to the present embodiment may include a semi-cured product of the resin composition as described above or include the uncured resin composition itself. In other words, the prepreg may be a prepreg including a semi-cured product of the resin composition (the resin composition in B stage) and a fibrous base material or a prepreg including the resin composition before being cured (the resin composition in A stage) and a fibrous base material. The resin composition or a semi-cured product of the resin composition may be one obtained by drying or heating and drying the resin composition.

When a prepreg is manufactured, the resin composition 2 is often prepared in a varnish form and used in order to be impregnated into the fibrous base material 3 which is a base material for forming the prepreg. In other words, the resin composition 2 is usually a resin varnish prepared in a varnish form in many cases. Such a varnish-like resin composition (resin varnish) is prepared, for example, as follows.

First, the respective components which can be dissolved in an organic solvent are introduced into and dissolved in an organic solvent. At this time, heating may be performed if necessary. Thereafter, components which are used if necessary but are not dissolved in the organic solvent are added to and dispersed in the solution until a predetermined dispersion state is achieved using a ball mill, a bead mill, a planetary mixer, a roll mill or the like, whereby a varnish-like resin composition is prepared. The organic solvent used here is not particularly limited as long as it dissolves the organic component, the resin component, or the like in the resin composition and does not inhibit the curing reaction. Specific examples thereof include toluene and methyl ethyl ketone (MEK).

Specific examples of the fibrous base material include glass cloth, aramid cloth, polyester cloth, a glass nonwoven fabric, an aramid nonwoven fabric, a polyester nonwoven fabric, pulp paper, and linter paper. When glass cloth is used, a laminate exhibiting excellent mechanical strength is obtained, and glass cloth subjected to flattening is particularly preferable. Specific examples of the flattening include a method in which glass cloth is continuously pressed at an appropriate pressure using a press roll to flatly compress the yarn. The thickness of the generally used fibrous base material is, for example, 0.01 mm or more and 0.3 mm or less. The glass fiber constituting the glass cloth is not particularly limited, and examples thereof include Q glass, NE glass, E glass, S glass, T glass, L glass, and L2 glass. The surface of the fibrous base material may be subjected to a surface treatment with a silane coupling agent. The silane coupling agent is not particularly limited, and examples thereof include a silane coupling agent having at least one selected from the group consisting of a vinyl group, an acryloyl group, a methacryloyl group, a styryl group, an amino group, and an epoxy group in the molecule.

The method for manufacturing the prepreg is not particularly limited as long as the prepreg can be manufactured. Specifically, when the prepreg is manufactured, the resin composition according to the present embodiment described above is often prepared in a varnish form and used as a resin varnish as described above.

Specific examples of the method for manufacturing the prepreg 1 include a method in which the fibrous base material 3 is impregnated with the resin composition 2, for example, the resin composition 2 prepared in a varnish form, and then dried. The fibrous base material 3 is impregnated with the resin composition 2 by dipping, coating, and the like. If necessary, the impregnation can be repeated a plurality of times. Moreover, at this time, it is also possible to finally adjust the composition and impregnated amount to the desired composition and impregnated amount by repeating impregnation using a plurality of resin compositions having different compositions and concentrations.

The fibrous base material 3 impregnated with the resin composition (resin varnish) 2 is heated under desired heating conditions, for example, at 40° C. or more and 180° C. or less for 1 minute or more and 10 minutes or less. By heating, the prepreg 1 before being cured (A-stage) or in a semi-cured state (B-stage) is obtained. By the heating, the organic solvent can be decreased or removed by being volatilized from the resin varnish.

The resin composition according to the present embodiment is a resin composition that can give a cured product having a high glass transition temperature and a low coefficient of thermal expansion. That is, when the resin composition is cured, a cured product having a high glass transition temperature and a low coefficient of thermal expansion is obtained. For this reason, the prepreg including the resin composition or the semi-cured product of the resin composition is a prepreg that can give a cured product having a high glass transition temperature and a low coefficient of thermal expansion. Therefore, this prepreg can be suitably used to produce a wiring board including an insulating layer containing a cured product having a high glass transition temperature and a low coefficient of thermal expansion.

### [Metal-Clad Laminate]

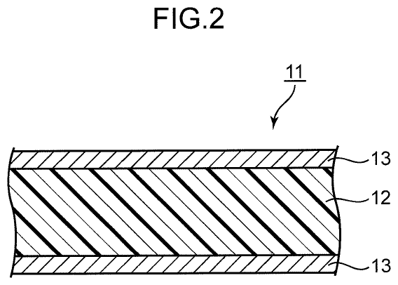

FIG. 2 is a schematic sectional view illustrating an example of a metal-clad laminate 11 according to an embodiment of the present invention.

As illustrated in FIG. 2, the metal-clad laminate 11 according to the present embodiment includes an insulating layer 12 containing a cured product of the resin composition and a metal foil 13 provided on the insulating layer 12. Examples of the metal-clad laminate 11 include a metal-clad laminate including an insulating layer 12 containing a cured product of the prepreg 1 illustrated in FIG. 1 and a metal foil 13 to be laminated together with the insulating layer 12. The insulating layer 12 may be formed of a cured product of the resin composition or a cured product of the prepreg. In addition, the thickness of the metal foil 13 varies depending on the performance and the like to be required for the finally obtained wiring board and is not particularly limited. The thickness of the metal foil 13 can be appropriately set depending on the desired purpose and is preferably, for example, 0.2 to 70 μm. Examples of the metal foil 13 include a copper foil and an aluminum foil, and the metal foil 13 may be a copper foil with carrier which includes a release layer and a carrier for the improvement in handleability in a case where the metal foil is thin.

The method for manufacturing the metal-clad laminate 11 is not particularly limited as long as the metal-clad laminate 11 can be manufactured. Specific examples thereof include a method in which the metal-clad laminate 11 is fabricated using the prepreg 1. Examples of this method include a method in which the double-sided metal foil-clad or single-sided metal foil-clad laminate 11 is fabricated by stacking one sheet or a plurality of sheets of prepreg 1, further stacking the metal foil 13 such as a copper foil on both or one of upper and lower surfaces of the prepregs 1, and laminating and integrating the metal foils 13 and prepregs 1 by heating and pressing. In other words, the metal-clad laminate 11 is obtained by laminating the metal foil 13 on the prepreg 1 and then performing heating and pressing. The heating and pressing conditions can be appropriately set depending on the thickness of the metal-clad laminate 11, the kind of the resin composition contained in the prepreg 1, and the like. For example, it is possible to set the temperature to 170° C. to 230° C., the pressure to 2 to 5 MPa, and the time to 60 to 150 minutes. The metal-clad laminate may be manufactured without using a prepreg. Examples thereof include a method in which a varnish-like resin composition is applied on a metal foil to form a layer containing the resin composition on the metal foil and then heating and pressing is performed.

The resin composition according to the present embodiment is a resin composition that can give a cured product having a high glass transition temperature and a low coefficient of thermal expansion. That is, when the resin composition is cured, a cured product having a high glass transition temperature and a low coefficient of thermal expansion is obtained. For this reason, the metal-clad laminate including an insulating layer containing a cured product of this resin composition is a metal-clad laminate including an insulating layer containing a cured product having a high glass transition temperature and a low coefficient of thermal expansion. This metal-clad laminate can be suitably used to produce a wiring board including an insulating layer containing a cured product having a high glass transition temperature and a low coefficient of thermal expansion.

### [Wiring Board]

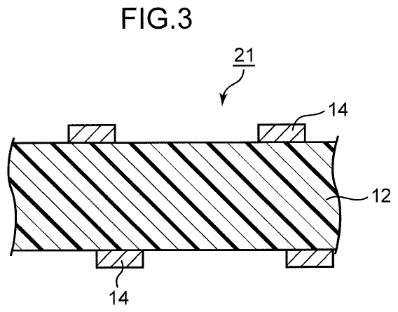

FIG. 3 is a schematic sectional view illustrating an example of a wiring board 21 according to an embodiment of the present invention.

As illustrated in FIG. 3, the wiring board 21 according to the present embodiment includes an insulating layer 12 containing a cured product of the resin composition and wiring 14 provided on the insulating layer 12. Examples of the wiring board 21 include a wiring board formed of an insulating layer 12 obtained by curing the prepreg 1 illustrated in FIG. 1 and wiring 14 which is laminated together with the insulating layer 12 and is formed by partially removing the metal foil 13. The insulating layer 12 may be formed of a cured product of the resin composition or a cured product of the prepreg.

The method for manufacturing the wiring board 21 is not particularly limited as long as the wiring board 21 can be manufactured. Specific examples thereof include a method in which the wiring board 21 is fabricated using the prepreg 1. Examples of this method include a method in which the wiring board 21, in which wiring is provided as a circuit on the surface of the insulating layer 12, is fabricated by forming wiring through etching and the like of the metal foil 13 on the surface of the metal-clad laminate 11 fabricated in the manner described above. In other words, the wiring board 21 is obtained by partially removing the metal foil 13 on the surface of the metal-clad laminate 11 and thus forming a circuit. Examples of the method for forming a circuit include circuit formation by a semi-additive process (SAP) or a modified semi-additive process (MSAP) in addition to the method described above.

The resin composition according to the present embodiment is a resin composition that can give a cured product having a high glass transition temperature and a low coefficient of thermal expansion. That is, when the resin composition is cured, a cured product having a high glass transition temperature and a low coefficient of thermal expansion is obtained. For this reason, the wiring board including an insulating layer containing a cured product of this resin composition is a wiring board including an insulating layer containing a cured product having a high glass transition temperature and a low coefficient of thermal expansion.

[Metal Foil with Resin]

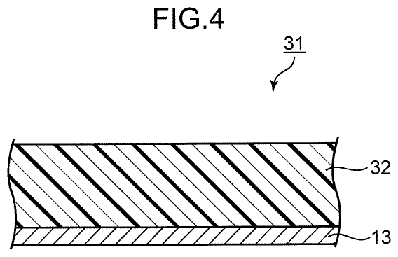

FIG. 4 is a schematic sectional view illustrating an example of a metal foil with resin 31 according to the present embodiment.

The metal foil with resin 31 according to the present embodiment includes a resin layer 32 containing the resin composition or a semi-cured product of the resin composition and a metal foil 13 as illustrated in FIG. 4. The metal foil with resin 31 includes the metal foil 13 on the surface of the resin layer 32. In other words, the metal foil with resin 31 includes the resin layer 32 and the metal foil 13 to be laminated together with the resin layer 32. The metal foil with resin 31 may include other layers between the resin layer 32 and the metal foil 13.

The resin layer 32 may contain a semi-cured product of the resin composition as described above or may contain the uncured resin composition. In other words, the metal foil with resin 31 may be a metal foil with resin including a resin layer containing a semi-cured product of the resin composition (the resin composition in B stage) and a metal foil or a metal foil with resin including a resin layer containing the resin composition before being cured (the resin composition in A stage) and a metal foil. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the metal foil, metal foils used in metal-clad laminates or metal foils with resin can be used without limitation. Examples of the metal foil include a copper foil and an aluminum foil.

The metal foil with resin 31 may include a cover film and the like if necessary. By including a cover film, it is possible to prevent entry of foreign matter and the like. The cover film is not particularly limited, and examples thereof include a polyolefin film, a polyester film, a polymethylpentene film, and films formed by providing a release agent layer on these films.

The method for manufacturing the metal foil with resin 31 is not particularly limited as long as the metal foil with resin 31 can be manufactured. Examples of the method for manufacturing the metal foil with resin 31 include a method in which the varnish-like resin composition (resin varnish) is applied on the metal foil 13 and heated to manufacture the metal foil with resin 31. The varnish-like resin composition is applied on the metal foil 13 using, for example, a bar coater. The applied resin composition is heated under the conditions of, for example, 40° C. or more and 180° C. or less and 0.1 minute or more and 10 minutes or less. The heated resin composition is formed as the uncured resin layer 32 on the metal foil 13. By the heating, the organic solvent can be decreased or removed by being volatilized from the resin varnish.

The resin composition according to the present embodiment is a resin composition that can give a cured product having a high glass transition temperature and a low coefficient of thermal expansion. That is, when the resin composition is cured, a cured product having a high glass transition temperature and a low coefficient of thermal expansion is obtained. For this reason, the metal foil with resin including the resin layer containing the resin composition or the semi-cured product of the resin composition is a metal foil with resin including a resin layer, which can give an insulating layer containing a cured product having a high glass transition temperature and a low coefficient of thermal expansion. Moreover, this metal foil with resin can be used when a wiring board including an insulating layer containing a cured product, which has a high glass transition temperature and a low coefficient of thermal expansion, is produced. For example, by laminating the metal foil with resin on a wiring board, a multilayer wiring board can be manufactured. As a wiring board obtained using such a metal foil with resin, a wiring board including an insulating layer containing a cured product, which has a high glass transition temperature and a low coefficient of thermal expansion, is obtained.

[Film with Resin]

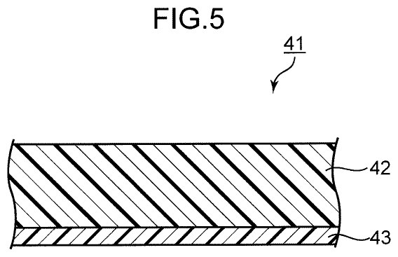

FIG. 5 is a schematic sectional view illustrating an example of a film with resin 41 according to the present embodiment.

The film with resin 41 according to the present embodiment includes a resin layer 42 containing the resin composition or a semi-cured product of the resin composition and a support film 43 as illustrated in FIG. 5. The film with resin 41 includes the resin layer 42 and the support film 43 to be laminated together with the resin layer 42. The film with resin 41 may include other layers between the resin layer 42 and the support film 43.

The resin layer 42 may contain a semi-cured product of the resin composition as described above or may contain the uncured resin composition. In other words, the film with resin 41 may be a film with resin including a resin layer containing a semi-cured product of the resin composition (the resin composition in B stage) and a support film or a film with resin including a resin layer containing the resin composition before being cured (the resin composition in A stage) and a support film. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the support film 43, support films used in films with resin can be used without limitation. Examples of the support film include electrically insulating films such as a polyester film, a polyethylene terephthalate (PET) film, a polyimide film, a polyparabanic acid film, a polyether ether ketone film, a polyphenylene sulfide film, a polyamide film, a polycarbonate film, and a polyarylate film.

The film with resin 41 may include a cover film and the like if necessary. By including a cover film, it is possible to prevent entry of foreign matter and the like. The cover film is not particularly limited, and examples thereof include a polyolefin film, a polyester film, and a polymethylpentene film.

The support film and the cover film may be those subjected to surface treatments such as a matt treatment, a corona treatment, a release treatment, and a roughening treatment if necessary.

The method for manufacturing the film with resin 41 is not particularly limited as long as the film with resin 41 can be manufactured. Examples of the method for manufacturing the film with resin 41 include a method in which the varnish-like resin composition (resin varnish) is applied on the support film 43 and heated to manufacture the film with resin 41. The varnish-like resin composition is applied on the support film 43 using, for example, a bar coater. The applied resin composition is heated under the conditions of, for example, 40° C. or more and 180° C. or less and 0.1 minute or more and 10 minutes or less. The heated resin composition is formed as the uncured resin layer 42 on the support film 43. By the heating, the organic solvent can be decreased or removed by being volatilized from the resin varnish.

The resin composition according to the present embodiment is a resin composition that can give a cured product having a high glass transition temperature and a low coefficient of thermal expansion. That is, when the resin composition is cured, a cured product having a high glass transition temperature and a low coefficient of thermal expansion is obtained. For this reason, the film with resin including a resin layer containing this resin composition or a semi-cured product of this resin composition is a film with resin including a resin layer, which affords a cured product having a high glass transition temperature and a low coefficient of thermal expansion. Moreover, this film with resin can be used when a wiring board including an insulating layer containing a cured product, which has a high glass transition temperature and a low coefficient of thermal expansion, is suitably produced. A multilayer wiring board can be manufactured, for example, by laminating the film with resin on a wiring board and then peeling off the support film from the film with resin or by peeling off the support film from the film with resin and then laminating the film with resin on a wiring board. As a wiring board obtained using such a film with resin, a wiring board including an insulating layer containing a cured product, which has a high glass transition temperature and a low coefficient of thermal expansion, is obtained.

This specification discloses technologies in various aspects as described above, and the main technologies among these are summarized below.

A resin composition according to a first aspect is a resin composition containing a maleimide compound (A) having an aromatic ring in a molecule and a maleimide equivalent of 500 g/mol or less; an imide compound (B) having a weight average molecular weight of 10,000 to 30,000 and a glass transition temperature of 50° C. or less; and a radical polymerizable compound (C).

A resin composition according to a second aspect is the resin composition according to the first aspect, in which the imide compound (B) has a glass transition temperature of 35° C. or less.

A resin composition according to a third aspect is the resin composition according to the first or second aspect, in which the imide compound (B) has a storage elastic modulus at 30° C. of 1×10⁵ to 5×10⁸ Pa.

A resin composition according to a fourth aspect is the resin composition according to any one of the first to third aspects, in which the imide compound (B) includes an imide compound (B-1) having a hydrocarbon group at a molecular end.

A resin composition according to a fifth aspect is the resin composition according to the fourth aspect, in which the imide compound (B-1) includes an imide compound (B-1-1) having, in a molecule, a structure represented by the following Formula (1):

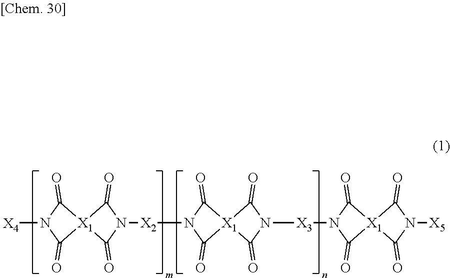

In Formula (1), X₁ represents a tetravalent tetracarboxylic acid residue, X₂ represents a divalent aliphatic diamine residue, X₃ represents a divalent aromatic diamine residue, X₄ and X₅ each independently represent a C₁₋₂₀ hydrocarbon group, a maleimide group, or an acid anhydride group, at least one of X₄ or X₅ represents a C₁₋₂₀ hydrocarbon group or a maleimide group, m represents 1 to 50, n represents 0 to 49, and a sum of m and n represents 1 to 50.

A resin composition according to a sixth aspect is the resin composition according to any one of the first to fifth aspects, in which the maleimide compound (A) includes a maleimide compound (A-1) having, in a molecule, an arylene structure bonded at a meta position.

A resin composition according to a seventh aspect is the resin composition according to any one of the first to sixth aspects, in which the radical polymerizable compound (C) includes a compound having an alkenyl group in a molecule.

A resin composition according to an eighth aspect is the resin composition according to any one of the first to seventh aspects, in which the radical polymerizable compound (C) includes at least one of a hydrocarbon-based compound (C-1) having an alkenyl-attached benzene ring in a molecule or an oxazine compound (C-2) having an alkenyl group in a molecule.

A resin composition according to a ninth aspect is the resin composition according to any one of the first to eighth aspects, in which a content of the maleimide compound (A) is 30 to 80 parts by mass based on total 100 parts by mass of the maleimide compound (A), the imide compound (B), and the radical reactive compound (C).

A resin composition according to a tenth aspect is the resin composition according to any one of the first to ninth aspects, in which a content of the imide compound (B) is 5 to 40 parts by mass based on total 100 parts by mass of the maleimide compound (A), the imide compound (B), and the radical reactive compound (C).

A resin composition according to an eleventh aspect is the resin composition according to any one of the first to tenth aspects, further containing a styrenic polymer (D).

A resin composition according to a twelfth aspect is the resin composition according to the eleventh aspect, in which the styrenic polymer (D) includes at least one selected from the group consisting of a methylstyrene (ethylene/butylene) methylstyrene block copolymer, a methylstyrene (ethylene-ethylene/propylene) methylstyrene block copolymer, a styrene isoprene block copolymer, a styrene isoprene styrene block copolymer, a styrene (ethylene/butylene) styrene block copolymer, a styrene (ethylene-ethylene/propylene) styrene block copolymer, a methylstyrene (styrene/butadiene random copolymer block) methylstyrene copolymer, and a styrene (styrene/butadiene random copolymer block) styrene copolymer.

A resin composition according to a thirteenth aspect is the resin composition according to any one of the eleventh or twelfth aspect, in which a content of the maleimide compound (A) is 30 to 70 parts by mass based on total 100 parts by mass of the maleimide compound (A), the imide compound (B), the radical reactive compound (C), and the styrenic polymer (D).

A resin composition according to a fourteenth aspect is the resin composition according to any one of the eleventh to thirteenth aspects, in which a content of the imide compound (B) is 5 to 40 parts by mass based on total 100 parts by mass of the maleimide compound (A), the imide compound (B), the radical reactive compound (C), and the styrenic polymer (D).

A resin composition according to a fifteenth aspect is the resin composition according to any one of the eleventh to fourteenth aspects, in which a content of the styrenic polymer (D) is 5 to 40 parts by mass based on total 100 parts by mass of the maleimide compound (A), the imide compound (B), the radical reactive compound (C), and the styrenic polymer (D).

A prepreg according to a sixteenth aspect is a prepreg including: the resin composition according to any one of the first to fifteenth aspects or a semi-cured product of the resin composition; and a fibrous base material.

A film with resin according to a seventeenth aspect is a film with resin including: a resin layer containing the resin composition according to any one of the first to fifteenth aspects or a semi-cured product of the resin composition; and a support film.

A metal foil with resin according to an eighteenth aspect is a metal foil with resin including: a resin layer containing the resin composition according to any one of the first to fifteenth aspects or a semi-cured product of the resin composition; and a metal foil.

A metal-clad laminate according to a nineteenth aspect is a metal-clad laminate including: an insulating layer containing a cured product of the resin composition according to any one of the first to fifteenth aspects; and a metal foil.

A metal-clad laminate according to a twentieth aspect is a metal-clad laminate including: an insulating layer containing a cured product of the prepreg according to the sixteenth aspect; and a metal foil.

A wiring board according to a twenty-first aspect is a wiring board including: an insulating layer containing a cured product of the resin composition according to any one of the first to fifteenth aspects; and a wiring.

A wiring board according to a twenty-second aspect is a wiring board including: an insulating layer containing a cured product of the prepreg according to the sixteenth aspect; and a wiring.

According to the present invention, it is possible to provide a resin composition, which affords a cured product having a high glass transition temperature and a low coefficient of thermal expansion. Furthermore, according to the present invention, it is possible to provide a prepreg, a film with resin, a metal foil with resin, a metal-clad laminate, and a wiring board, which are obtained using the resin composition.

Hereinafter, the present invention will be described more specifically with reference to Examples, but the scope of the present invention is not limited thereto.

### EXAMPLES

### Examples 1 to 5 and Comparative Examples 1 to 6

The respective components to be used at the time of preparing a resin composition in the present Examples will be described.

### (Maleimide Compound)

Maleimide compound-1: 3,3′-Dimethyl-5,5′-diethyl-4,4′-diphenylmethanebismaleimide (BMI-5100 manufactured by Daiwa Kasei Industry Co., Ltd.; bismaleimide compound; maleimide equivalent: 221 g/mol)

Maleimide compound-2: Maleimide compound having, in the molecule, an arylene structure substituted at the meta position (solid component in MIR-5000-60T (maleimide compound dissolved in toluene) manufactured by Nippon Kayaku Co., Ltd.; maleimide compound represented by Formula (4); maleimide equivalent: 260 g/mol)

### (Imide Compound)

Imide compound-1: Imide compound having, in the molecule, a structure represented by Formula (1), where X₄ and X₅ are each a hydrocarbon group (solid content in VA-9608 manufactured by TOYOCHEM CO., LTD.; weight average molecular weight: 13,000; acid value: 1.8 mgKOH/g; glass transition temperature Tg: 22° C.; storage elastic modulus G′: 5.7 MPa)

Imide compound-2: Imide compound having, in the molecule, a structure represented by Formula (1), where X₄ and X₅ are each a hydrocarbon group (solid content in VA-9603 manufactured by TOYOCHEM CO., LTD.; weight average molecular weight: 12,000; acid value: 3.4 mgKOH/g; glass transition temperature Tg: 88° C.; storage elastic modulus G′: 1200 MPa)

Imide compound-3: Imide compound having, in the molecule, a structure represented by Formula (1), where X₄ and X₅ are each a hydrocarbon group (solid content in VA-9609 manufactured by TOYOCHEM CO., LTD.; weight average molecular weight: 13,000; acid value: 1.8 mgKOH/g; glass transition temperature Tg: 55° C.; storage elastic modulus G′: 950 MPa)

Imide compound-4: N-Alkylbismaleimide compound (BMI-1500 manufactured by Designer Molecules Inc.; weight average molecular weight: 1,500; liquid at room temperature)

Note that the glass transition temperature Tg and the storage elastic modulus G′ of each imide compound were measured as follows. First, the imide compound (B) was dissolved in a mixed solvent of toluene and methyl ethyl ketone (MEK) so that a nonvolatile content was 35% by mass. The resulting solution was applied onto a heat-resistant release film by using a doctor blade having a gap of 10 mil (about 254 μm), and dried at 120° C. for 5 minutes to produce a sheet having a thickness of 25 μm on the release film. The obtained sheet was peeled off from the release film, and the glass transition temperature Tg and the storage elastic modulus G′ of the detached sheet (sheet including the imide compound) were measured using a dynamic viscoelasticity analyzer (DVA 200 manufactured by IT Measurement Control Co., Ltd.). As the measurement conditions, the sheet was cooled to −30° C. and then heated to 300° C. at a temperature raising rate of 10° C./min. In addition, the measurement was performed under the conditions at a vibration frequency of 10 Hz, a length between grips of 10 mm, and a width of 5 mm. Note that these measurement conditions were one example and were adjusted depending on the imide compound. Specifically, the measurement conditions were adjusted such that the measurement start temperature was lower than the glass transition temperature depending on the glass transition temperature or the like of the imide compound to be measured.

### (Radical Polymerizable Compound)

Radical polymerizable compound-1: Benzoxazine compound having, in the molecule, an allyl group (benzoxazine compound represented by Formula (10), where R₃ and R₄ are each an allyl group, X₆ is a methylene group, and q and r are 1; ALPd manufactured by SHIKOKU CHEMICALS CORPORATION)

Radical polymerizable compound-2: Compound represented by Formula (11) (SD-5 manufactured by Sanko Co., Ltd.)

Radical polymerizable compound-3: Divinylbenzene (DVB) (DVB-810 manufactured by NIPPON STEEL & SUMITOMO METAL Corporation; monomer, liquid; molecular weight: 130; number of terminal double bonds: 2)

### (Styrenic Polymer)

Styrenic polymer: Hydrogenated styrene (ethylene butylene) styrene copolymer (Tuftec H1041 manufactured by Asahi Kasei Corporation; copolymer having, in the molecule, repeating units represented by Formulas (13) to (15), (22), and (23) above and where b:c:d:k:l is 51:28:18:2:1; weight average molecular weight: 80,000)

### (Epoxy Resin)

Epoxy resin-1: Epoxidized polybutadiene (JP-100, manufactured by Nippon Soda Co., Ltd.; epoxidized polybutadiene having an epoxy group introduced by oxidation of a vinyl group of 1,2-polybutadiene)

Epoxy resin-2: Naphthalene-type epoxy resin (IIP 9500 manufactured by DIC Corporation)

### (Reaction Initiator)

Reaction initiator: α,α′-Di(t-butylperoxy)diisopropylbenzene (PBP) (Perbutyl P manufactured by NOF CORPORATION)

### (Curing Accelerator)

Curing accelerator: 2-Ethyl-4-methylimidazole (2E4MZ) (2E4MZ manufactured by SHIKOKU CHEMICALS CORPORATION)

### (Silane Coupling Agent)

Silane coupling agent: 3-Methacryloxypropyltrimethoxysilane (KBM-503 manufactured by Shin-Etsu Chemical Co., Ltd.)

### (Inorganic Filler)

Silica: Silica filler (silica particles subjected to surface treatment with a silane coupling agent having a phenylamino group in the molecule; SC2500-SXJ manufactured by Admatechs Company Limited)

Zinc molybdate: Zinc molybdate filler (Z4SX-A1 manufactured by Admatechs Company Limited)

### [Preparation Method]

First, components other than the inorganic filler were added at the composition (parts by mass) presented in Table 1 to a mixed solvent of toluene and methyl ethyl ketone (MEK) (mass ratio:about 1:1) so that the solid concentration was 50% by mass, and the mixture was then mixed. The resulting mixture was stirred for 60 minutes. Thereafter, in the case of containing the inorganic filler, the inorganic filler was added at the composition (parts by mass) presented in Table 1 to the obtained mixture, and dispersed using a bead mill. By doing so, a varnish-like resin composition (varnish) was obtained.

Next, the following procedure was used to produce a prepreg.

A fibrous base material (Glass cloth: #2118 type, T glass manufactured by Nitto Boseki Co., Ltd.) was impregnated with the obtained varnish, and then heated and dried at 130° C. for 3 minutes to prepare a prepreg. At that time, the content (resin content) of the components constituting the resin with respect to the prepreg was adjusted to be about 43% by mass by the curing reaction. Further, the post-curing thickness was adjusted to 103 μm.

Next, an evaluation substrate (metal-clad laminate) was obtained as follows.

First, 12 sheets of the resulting prepreg were stacked, and copper foils (3EC-VLP manufactured by Mitsui Mining & Smelting Corporation) with a thickness of 12 m were disposed on both sides of the stacked prepregs. This as a body to be pressed was heated to a temperature of 220° C. at a temperature raising rate of 3° C./min and heated and pressed for 120 minutes under the conditions at 220° C. and a pressure of 3 MPa, thereby obtaining an evaluation substrate (metal-clad laminate) having copper foil bonded to both surfaces and having a resin layer thickness of about 1240 μm.

The evaluation substrates fabricated as described above were evaluated by the methods described below.

### [Glass Transition Temperature (Tg)]

Using an unclad substrate obtained by removing the copper foil from the evaluation substrate (metal-clad laminate) by etching as a test piece, the Tg of the cured product of the resin composition was measured by a viscoelastic spectrometer “DMS6100” manufactured by Seiko Instruments Inc. At this time, dynamic viscoelasticity analysis (DMA) was performed with a bending module at a frequency of 10 Hz, and the temperature at which tan 8 was maximized when the temperature was raised from room temperature to 340° C. at a temperature raising rate of 5° C./min was taken as Tg (° C.). When the glass transition temperature acquired by the analysis was 260° C. or higher, it was determined as “Acceptable”.

### [Coefficient of Thermal Expansion-1]

Using an unclad substrate obtained by removing the copper foil from the evaluation substrate (metal-clad laminate) by etching as a test piece, the coefficient of thermal expansion in the surface direction of the evaluation substrate (tensile direction, Y direction) at a temperature less than the glass transition temperature of a cured product of the resin composition was measured by the TMA (Thermo-mechanical analysis) method. Specifically, a TMA system (“TMA6000” manufactured by SII NanoTechnology Inc.) was used for the measurement, and the measurement was performed in a compression mode. In order to eliminate the influence of thermal strain of the test piece, the temperature of the test piece was raised from 30° C. to 320° C. at a temperature raising rate of 10° C./min while the test piece was pulled in the Y direction at a load of 10 g, and then the test piece was cooled to room temperature. Thereafter, the test piece was heated from 30° C. to 320° C. at a temperature raising rate of 10° C./min while being pulled in the Y direction at a load of 10 g. A temperature change chart was obtained at the time of this temperature rise. Then, an average coefficient of thermal expansion at 50 to 100° C. was calculated from the temperature change chart obtained at that time. A smaller average coefficient of thermal expansion (Y-CTE 50-100° C.) means a more preferable result, and in this test, the case where the average coefficient of thermal expansion is less than 6 ppm/° C. is determined as “Acceptable”.

### [Coefficient of Thermal Expansion-2]

From the temperature change chart obtained at the time of measuring the coefficient of thermal expansion (CTE)-1, an average coefficient of thermal expansion at 50 to 260° C. was calculated. A smaller average coefficient of thermal expansion (Y-CTE 50-260° C.) means a more preferable result, and in this test, the case where the average coefficient of thermal expansion is less than 6 ppm/° C. is determined as “Acceptable”.

The results in each of the above evaluations are shown in Table 1 together with the components of each resin composition.

TABLE 1

| | | | Examples | | | | | Comparative Example | | | | | |
|---|---|---|---|---|---|---|---|---|---|---|---|---|---|
| | | | 1 | 2 | 3 | 4 | 5 | 1 | 2 | 3 | 4 | 5 | 6 |
| Component | Maleimide compound-1 | | 15 | 15 | 15 | 20 | 20 | 15 | 15 | 15 | 15 | 28.6 | 20 |
| (parts by | Maleimide compound-2 | | 20 | 20 | 20 | 20 | 20 | 20 | 20 | 20 | 20 | 28.6 | 20 |
| mass) | Imide compound-1 | | 30 | 10 | 10 | 30 | 20 | — | — | — | — | — | — |
| | Imide compound-2 | | — | — | — | — | — | — | 10 | — | — | — | 30 |
| | Imide compound-3 | | — | — | — | — | — | — | — | 10 | — | — | — |
| | Imide compound-4 | | — | — | — | — | — | — | — | — | 30 | — | — |
| | Radical polymerizable compound-1 | | 30 | 30 | — | 30 | 30 | 30 | 30 | 30 | — | 42.8 | 30 |
| | Radical polymerizable compound-2 | | — | — | 10 | — | — | — | — | — | 30 | — | — |
| | Radical polymerizable compound-3 | | — | — | 20 | — | — | — | — | — | — | — | — |
| | Styrenic polymer | | — | 20 | 20 | — | 10 | 30 | 20 | 20 | — | — | — |
| | Epoxy resin-1 | | 5 | 5 | 5 | — | — | 5 | 5 | 5 | — | — | — |
| | Epoxy resin-2 | | — | — | — | — | — | — | — | — | 5 | — | — |
| | Reaction initiator | | 1 | 1 | 1 | 1 | 1 | 1 | 1 | 1 | 1 | 1 | 1 |
| | Curing accelerator | | 1 | 1 | 1 | 0.1 | 0.1 | 1 | 1 | 1 | 1 | 0.1 | 0.1 |
| | Silane coupling agent | | 1 | 1 | 1 | — | — | 1 | 1 | 1 | 1 | — | — |
| | Inorganic filler | Silica | 119 | 119 | 119 | 120 | 120 | 119 | 119 | 119 | 119 | 120 | 120 |
| | | Zinc molybdate | 12 | 12 | 12 | — | — | 12 | 12 | 12 | 12 | — | — |

| | | | | | | | | | | | | |
|---|---|---|---|---|---|---|---|---|---|---|---|---|
| Evaluation | Glass transition temperature Tg (° C.) | 287 | 285 | 327 | 301 | 299 | 279 | 280 | 273 | 277 | 298 | 297 |
| | Coefficient of thermal expansion-1 (ppm/° C.) | 4.9 | 5.4 | 5.1 | 5.7 | 5.9 | 6.0 | 7.0 | 7.2 | 8.0 | 8.1 | 9.4 |
| | Coefficient of thermal expansion-2 (ppm/° C.) | 4.7 | 4.9 | 4.7 | 5.4 | 5.6 | 6.0 | 6.4 | 5.8 | 7.3 | 9.0 | 5.8 |

As can be seen from Table 1, an imide compound (B) having a weight average molecular weight of 10,000 to 30,000 and a glass transition temperature of 50° C. or less was included in a resin composition containing a maleimide compound (A) having an aromatic ring in the molecule and a maleimide equivalent of 500 g/mol or less and a radical polymerizable compound (C) (Examples 1 to 5). In these cases, a resin composition was obtained that gave a cured product having a higher glass transition temperature and a lower coefficient of thermal expansion than the cases without any imide compound (Comparative Examples 1 and 5) or the cases including an imide compound different from the imide compound (B) (Comparative Examples 2 to 4 and 6).

Properties (copper foil peel strength, interlayer peel strength, and desmear property) other than the glass transition temperature and the coefficient of thermal expansion of the resin composition containing the maleimide compound (A), the imide compound (B), and the radical polymerizable compound (C) were also examined.

### [Copper Foil Peel Strength]

The copper foil was peeled off from the evaluation substrate (metal-clad laminate), and the peel strength at that time was measured in conformity with JIS C 6481 (1996). Specifically, the copper foil was peeled off from the evaluation substrate at a speed of 50 mm/min using a tensile tester, and the peel strength (N/mm) at that time was measured. This peel strength is the copper foil peel strength, and it can be seen that the adhesion of the metal foil (copper foil) is higher as this peel strength is higher.

### [Interlayer Peel Strength]

The uppermost insulating layer (prepreg) in the evaluation substrate (metal-clad laminate) was peeled off from the second insulating layer (prepreg) at a speed of 50 mm/min by a tensile tester, and the peel strength (N/mm) at that time was measured. This peel strength is the interlayer peel strength, and it is found that the higher the peel strength, the higher the interlayer adhesion.

### [Desmear Property (Desmear Etching Rate)]

First, the copper foil on the surface of the evaluation substrate (metal-clad laminate) was removed by etching. As a desmear process, the substrate from which the copper foil was removed was immersed in a swelling liquid (Swelling Dip Securiganth P manufactured by Atotech) at 60° C. for 5 minutes, then immersed in an aqueous potassium permanganate solution (Concentrate Compact CP manufactured by Atotech) at 80° C. for 10 minutes, and then subjected to neutralization. This procedure was repeated twice. Before and after such a desmear process, the weight of the substrate was measured, and the amount of weight decrease (weight of substrate before desmear process−weight of substrate after desmear process) due to the desmear process was calculated, and the amount of weight decrease per 1 cm² (mg/cm²) was calculated from the amount of weight decrease. The larger the amount of weight decrease per 1 cm², the higher the desmear etching rate. If the desmear etching rate is too low or too high, it cannot be said that the desmear property is high, and there is a required appropriate desmear etching rate. That is, when the amount of weight decrease per 1 cm² is too small or too large, it cannot be said that the desmear property is high, and there is a required appropriate amount of weight decrease. For example, the amount of weight decrease per 1 cm² is preferably 0.1 mg/cm² or more and less than 0.55 mg/cm², and more preferably 0.1 mg/cm² or more and less than 0.4 mg/cm².

The results are presented in Table 2.

TABLE 2

Examples

| | 1 | 2 | 3 | 4 | 5 |
|---|---|---|---|---|---|
| Copper foil peel | 0.25 | 0.43 | 0.39 | 0.21 | 0.35 |
| strength (N/mm) | | | | | |
| Interlayer peel | 0.24 | 0.54 | 0.60 | 0.20 | 0.40 |
| strength (N/mm) | | | | | |
| Desmear etching | 0.29 | 0.32 | 0.68 | 0.54 | 0.48 |
| rate (mg/cm²) | | | | | |

In the cases of containing the maleimide compound (A), the imide compound (B), and the radical polymerizable compound (C) (Examples 1 to 5), as described above, it has been found from Table 1 that a resin composition was obtained that gives a cured product having a high glass transition temperature and a low coefficient of thermal expansion. Further, from Table 2, it has been found that the cases of further including the styrenic polymer (D) (Examples 2, 3, and 5) had a higher copper foil peel strength and interlayer peel strength than the cases without the styrenic polymer (D) (Examples 1 and 4). Furthermore, from Table 2, it has been found that the cases of including, as the radical polymerizable compound (C), the oxazine compound (C-2) (Examples 1, 2, 4, and 5) had a better desmear etching rate than the case of including another radical polymerizable compound (C-3) (Example 3), so that the desmear property was excellent.

This application is based on Japanese patent application No. 2022-200257 filed on Dec. 15, 2022, the contents of which are included in the present application.

In order to express the present invention, the present invention has been described above appropriately and sufficiently through the embodiments. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

According to the present invention, there is provided a resin composition, which affords a cured product having a high glass transition temperature and a low coefficient of thermal expansion. In addition, the present invention provides a prepreg, a film with resin, a metal foil with resin, a metal-clad laminate, and a wiring board which are obtained using the resin composition.

1. A resin composition comprising:
a maleimide compound (A) having an aromatic ring in a molecule and a maleimide equivalent of 500 g/mol or less;
an imide compound (B) having a weight average molecular weight of 10,000 to 30,000 and a glass transition temperature of 50° C. or less; and
a radical polymerizable compound (C).

2. The resin composition according to claim 1, wherein the imide compound (B) has a glass transition temperature of 35° C. or less.

3. The resin composition according to claim 1, wherein the imide compound (B) has a storage elastic modulus at 30° C. of 1×10⁵ to 5×10⁸ Pa.

4. The resin composition according to claim 1, wherein the imide compound (B) includes an imide compound (B-1) having a hydrocarbon group at a molecular end.

5. The resin composition according to claim 4, wherein
the imide compound (B-1) includes an imide compound (B-1-1) having, in a molecule, a structure represented by the following Formula (1): 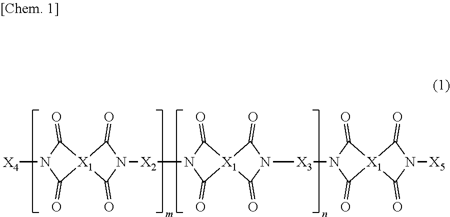
wherein in Formula (1), X₁ represents a tetravalent tetracarboxylic acid residue, X₂ represents a divalent aliphatic diamine residue, X₃ represents a divalent aromatic diamine residue, X₄ and X₅ each independently represent a C₁₋₂₀ hydrocarbon group, a maleimide group, or an acid anhydride group, at least one of X₄ or X₅ represents a C₁₋₂₀ hydrocarbon group or a maleimide group, m represents 1 to 50, n represents 0 to 49, and a sum of m and n represents 1 to 50.

6. The resin composition according to claim 1, wherein the maleimide compound (A) includes a maleimide compound (A-1) having, in a molecule, an arylene structure bonded at a meta position.

7. The resin composition according to claim 1, wherein the radical polymerizable compound (C) includes an alkenyl group in a molecule.

8. The resin composition according to claim 1, wherein the radical polymerizable compound (C) includes at least one of a hydrocarbon-based compound (C-1) having an alkenyl-attached benzene ring in a molecule or an oxazine compound (C-2) having an alkenyl group in a molecule.

9. The resin composition according to claim 1, wherein a content of the maleimide compound (A) is 30 to 80 parts by mass based on total 100 parts by mass of the maleimide compound (A), the imide compound (B), and the radical polymerizable compound (C).

10. The resin composition according to claim 1, wherein a content of the imide compound (B) is 5 to 40 parts by mass based on total 100 parts by mass of the maleimide compound (A), the imide compound (B), and the radical polymerizable compound (C).

11. The resin composition according to claim 1, further comprising a styrenic polymer (D).

12. The resin composition according to claim 11, wherein the styrenic polymer (D) includes at least one selected from the group consisting of a methylstyrene (ethylene/butylene) methylstyrene block copolymer, a methylstyrene (ethylene-ethylene/propylene) methylstyrene block copolymer, a styrene isoprene block copolymer, a styrene isoprene styrene block copolymer, a styrene (ethylene/butylene) styrene block copolymer, a styrene (ethylene-ethylene/propylene) styrene block copolymer, a methylstyrene (styrene/butadiene random copolymer block) methylstyrene copolymer, and a styrene (styrene/butadiene random copolymer block) styrene copolymer.

13. The resin composition according to claim 11, wherein a content of the maleimide compound (A) is 30 to 70 parts by mass based on total 100 parts by mass of the maleimide compound (A), the imide compound (B), the radical polymerizable compound (C), and the styrenic polymer (D).

14. The resin composition according to claim 11, wherein a content of the imide compound (B) is 5 to 40 parts by mass based on total 100 parts by mass of the maleimide compound (A), the imide compound (B), the radical polymerizable compound (C), and the styrenic polymer (D).

15. The resin composition according to claim 11, wherein a content of the styrenic polymer (D) is 5 to 40 parts by mass based on total 100 parts by mass of the maleimide compound (A), the imide compound (B), the radical polymerizable compound (C), and the styrenic polymer (D).

16. A prepreg comprising:
the resin composition according to claim 1 or a semi-cured product of the resin composition; and
a fibrous base material.

17. A film with resin comprising:
a resin layer containing the resin composition according to claim 1 or a semi-cured product of the resin composition; and
a support film.

18. A metal foil with resin comprising:
a resin layer containing the resin composition according to claim 1 or a semi-cured product of the resin composition; and
a metal foil.

19. A metal-clad laminate comprising:
an insulating layer containing a cured product of the resin composition according to claim 1; and
a metal foil.

20. A metal-clad laminate comprising:
an insulating layer containing a cured product of the prepreg according to claim 16; and
a metal foil.

21. A wiring board comprising:
an insulating layer containing a cured product of the resin composition according to claim 1; and
a wiring.

22. A wiring board comprising:
an insulating layer containing a cured product of the prepreg according to claim 16; and
a wiring.
